(19) United States
(12) Patent Application Publication
(10) Pub. No.: US 2025/0261528 A1
(43) Pub. Date: Aug. 14, 2025

(54) DISPLAY DEVICE

(71) Applicant: Samsung Display Co., Ltd., Yongin-si (KR)

(72) Inventors: SEUNGSUE RYU, Yongin-si (KR); HONGAM KIM, Yongin-si (KR); HANHO PARK, Yongin-si (KR)

(73) Assignee: Samsung Display Co., Ltd., Yongin-si (KR)

(21) Appl. No.: 19/023,950

(22) Filed: Jan. 16, 2025

(30) Foreign Application Priority Data
Feb. 14, 2024 (KR) 10-2024-0021316

(51) Int. Cl. H10K 59/131

(52) U.S. Cl. CPC H10K 59/131

(57) ABSTRACT

A display device including a display panel and a driving chip. The display panel includes first row output pads and second row output pads. The driving chip includes first row output bumps and second row output bumps. Each of the first row output pads and the second row output pads includes first output pads and second output pads arranged alternately with the first output pads. Each of the first row output bumps and the second row output bumps includes first output bumps and second output bumps. The second output pads are shifted from the first output pads in a second direction by a predetermined or selected distance, and the second output bumps are shifted from the first output bumps in the second direction by a predetermined or selected distance.

### CROSS-REFERENCE TO RELATED APPLICATION(S)

This application claims priority to and benefits of Korean Patent Application No. 10-2024-0021316 under 35 U.S.C. § 119, filed on Feb. 14, 2024 in the Korean Intellectual Property Office, the entire contents of which are incorporated herein by reference.

### BACKGROUND

### 1. Technical Field

Embodiments relate to a display device in which a driving chip is mounted on a substrate.

### 2. Description of the Related Art

Various display devices used in multimedia devices such as televisions, mobile phones, tablet computers, navigation devices, and game consoles have been developed. These display devices include multiple electronic components. The electronic components may include a display panel, a driving chip, a circuit board, and the like. These electronic components may be electrically connected through various methods.

### SUMMARY

Embodiments of the disclosure provide a display device including a driving chip mounted on a substrate without cracks or damage.

According to an embodiment, a display device may include a display panel including a plurality of first row output pads arranged in a first direction and a plurality of second row output pads spaced apart from the plurality of first row output pads in a second direction intersecting the first direction by a first distance, and a driving chip including a plurality of first row output bumps arranged in the first direction and contacting the plurality of first row output pads and a plurality of second row output bumps spaced apart from the plurality of first row output bumps in the second direction by a second distance that is greater than or equal to the first distance and contacting the plurality of second row output pads. Each of the plurality of first row output pads and the plurality of second row output pads may include a plurality of first output pads arranged in the first direction, and a plurality of second output pads aligned in the first direction, arranged alternately with the first plurality of output pads in the first direction, and shifted from the plurality of first output pads in the second direction by a fourth distance. Each of the plurality of first row output bumps and the plurality of second row output bumps may include a plurality of first output bumps aligned in the first direction and contacting the plurality of first output pads, and a plurality of second output bumps aligned in the first direction, connected to the plurality of second output pads, and shifted from the plurality of first output bumps in the second direction by a third distance.

The fourth distance may be smaller than the first distance.

The third distance may be smaller than the second distance.

The fourth distance may be smaller than or equal to the third distance.

The plurality of first output pads of the plurality of first row output pads may be aligned with the plurality of second output pads of the plurality of second row output pads in the second direction, and the plurality of second output pads of the plurality of first row output pads may be aligned with the plurality of first output pads of the plurality of second row output pads in the second direction.

The display panel further may include a plurality of pixels, and a plurality of signal lines connecting the plurality of pixels with both the plurality of first row output pads and the plurality of second row output pads, wherein the plurality of signal lines may include a first signal line group including signal lines arranged between one of the first output pads and one of the second output pads adjacent to each other among the plurality of first row output pads, and a second signal line group including signal lines spaced apart from the first signal line group in the first direction with the one of the plurality of second output pads interposed between the first signal line group and the second signal line group, and each of the first signal line group and the second signal line group may include a first signal line connected to any one of the plurality of first output pads and the plurality of second output pads, and a second signal line electrically insulated from the first signal line.

Each of the plurality of signal lines may include a first line part parallel to the second direction, a second line part parallel to the second direction and spaced apart from the first line part in the second direction, and a connection part connecting the first line part and the second line part and inclined in the first direction and the second direction, and the second line part may be shifted from the first line part in the first direction.

Each connection part of the signal lines of the first signal line group and each connection part of the plurality of signal lines of the second signal line group may be aligned in the first direction.

Each of the plurality of pixels may include a first transistor including a first gate, and a second transistor including a second gate disposed on a different layer from the first gate, the first signal line and the first gate may be disposed on a same layer, and the second signal line and the second gate may be disposed on a same layer.

The first signal line and the second signal line may not overlap each other in plan view.

The display device may further include a connector passing through an insulating layer disposed on one of the plurality of first output pads and connected to the one of the plurality of first output pads, and one of the plurality of first output bumps may be electrically connected to the one of the plurality of first output pads through the connection part.

Each of the first signal line group and the second signal line group may further include a third signal line electrically insulated from the second signal line and spaced apart from the first signal line with the second signal line interposed between the third signal line and the first signal line, each of the first to third signal lines may include a first line part parallel to the second direction, a second line part parallel to the second direction, spaced apart from the first line part in the second direction, and shifted from the first line part in the first direction, and a connection part connecting the first line part and the second line part and inclined in the first direction and the second direction, and the first line part or the second line part of the third signal line may further include an inclined portion shifted from the connection part of the third signal line in the first direction.

Each connection part of the first to third signal lines may be aligned in the first direction, and the fourth distance may be greater than or equal to the first distance.

The display panel may further include a plurality of input pads spaced apart from the plurality of second row output pads in the second direction and arranged in the first direction, wherein the driving chip may further include a plurality of input bumps spaced apart from the plurality of second row output bumps in the second direction and connected to the plurality of input pads, and the plurality of input bumps may include a plurality of first input bumps aligned in the first direction, and a plurality of second input bumps aligned in the first direction, arranged alternately with the plurality of first input bumps in the first direction, and shifted from the plurality of first input bumps in the second direction by a fifth distance.

The plurality of input pads may include a plurality of first input pads aligned in the first direction and electrically connected to the plurality of first input bumps, and a plurality of second input pads aligned in the first direction and electrically connected to the plurality of second input bumps, and the plurality of second input pads may be shifted from the plurality of first input pads in the second direction by a sixth distance.

The sixth distance may be smaller than or equal to the fifth distance.

According to an embodiment, a display device may include a display panel including a plurality of first row output pads arranged in a first direction, a plurality of second row output pads spaced apart from the plurality of first row output pads in a second direction intersecting the first direction by a first distance, and a plurality of input pads spaced apart from the plurality of second row output pads in the second direction and arranged in the first direction, and a driving chip including a plurality of first row output bumps arranged in the first direction and connected to the plurality of first row output pads, a plurality of second row output bumps spaced apart from the plurality of first row output bumps in the second direction by a second distance that is greater than or equal to the first distance and connected to the plurality of second row output pads, and a plurality of input bumps spaced apart from the plurality of second row output bumps in the second direction and connected to the plurality of input pads. Each of the plurality of first row output bumps and the plurality of second row output bumps may include a plurality of first output bumps aligned in the first direction, and a plurality of second output bumps aligned in the first direction, arranged alternately with the plurality of first output bumps in the first direction, and shifted from the plurality of first output bumps in the second direction by a third distance. The plurality of input bumps may include a plurality of first input bumps aligned in the first direction, and a plurality of second input bumps aligned in the first direction, arranged alternately with the plurality of first input bumps in the first direction, and shifted from the plurality of first input bumps in the second direction.

Each of the plurality of first row output pads and the plurality of second row output pads may include a plurality of first output pads aligned in the first direction and electrically connected to the plurality of first output bumps, and a plurality of second output pads aligned in the first direction, arranged alternately with the plurality of first output pads in the first direction, and electrically connected to the plurality of second output bumps, and the plurality of second output pads may be shifted from the first output pads in the second direction by a fourth distance.

The plurality of input pads may include a plurality of first input pads aligned in the first direction and electrically connected to the plurality of first input bumps, and a plurality of second input pads aligned in the first direction and electrically connected to the plurality of second input bumps, and the second input pads may be shifted from the plurality of first input pads in the second direction.

### BRIEF DESCRIPTION OF THE DRAWINGS

The above and other aspects and features of the disclosure will become apparent by describing in detail embodiments thereof with reference to the accompanying drawings.

FIG. 1A is a schematic perspective view of a display device according to an embodiment of the disclosure.

FIG. 1B is an exploded schematic perspective view of the display device according to an embodiment of the disclosure.

FIGS. 2A and 2B are schematic cross-sectional views of the display device according to an embodiment of the disclosure.

FIG. 3A is a schematic plan view of a display panel according to an embodiment of the disclosure.

FIG. 3B is a schematic cross-sectional view of the display panel according to an embodiment of the disclosure.

FIG. 4 is an exploded schematic perspective view of a bonding area of the display device according to an embodiment of the disclosure.

FIG. 5 is a schematic plan view of a chip area of the display device according to an embodiment of the disclosure.

FIGS. 6A and 6B are enlarged schematic views of a portion of the chip area of the display device according to an embodiment of the disclosure.

FIG. 7 is an enlarged schematic view of the portion of the chip area of the display device according to an embodiment of the disclosure.

FIGS. 8A to 8C are enlarged schematic plan views of a portion of a pad area of the display device according to an embodiment of the disclosure.

FIGS. 8D and 8E are enlarged schematic cross-sectional views of the portion of the pad area of the display device according to an embodiment of the disclosure.

FIGS. 9A to 9C are enlarged schematic plan views of the portion of the pad area of the display device according to an embodiment of the disclosure.

FIG. 10 is an enlarged schematic plan view of the portion of the pad area of the display device according to an embodiment of the disclosure.

FIG. 11 is a schematic plan view of the chip area of the display device according to an embodiment of the disclosure.

FIGS. 12A and 12B are enlarged schematic plan views of the portion of the pad area of the display device according to an embodiment of the disclosure.

FIG. 13 is a schematic plan view of the chip area of the display device according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

As used herein, the singular forms, “a,” “an,” and “the” are intended to include the plural forms as well, unless the context clearly indicates otherwise.

The expression that a first component (or area, layer, part, portion, etc.) is “disposed on”, “connected with” or “coupled to” a second component means that the first component is directly disposed on/connected with/coupled to the second component or means that a third component is interposed therebetween.

The same reference numerals refer to the same components. Further, in the drawings, the thickness, the ratio, and the dimension of components may be exaggerated for effective description of technical contents.

The term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

The phrase “at least one of” is intended to include the meaning of “at least one selected from the group of” for the purpose of its meaning and interpretation. For example, “at least one of A and B” may be understood to mean “A, B, or A and B.”

Although the terms “first”, “second”, etc. may be used to describe various components, the components should not be limited by the terms. The terms are only used to distinguish one component from another component. For example, without departing from the right scope of the disclosure, a first component may be referred to as a second component, and similarly, the second component may also be referred to as the first component.

The terms “under”, “below”, “on”, “above”, etc. are used to describe the correlation of components illustrated in drawings. The terms that are relative in concept are described based on a direction illustrated in drawings.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or “to not overlap” another element, this may include that the elements are spaced apart from each other, offset from each other, or set aside from each other or any other suitable term as would be appreciated and understood by those of ordinary skill in the art.

It will be understood that the terms “include”, “comprise”, “have”, etc. specify the presence of features, numbers, steps, operations, elements, or components, described in the specification, or a combination thereof, and do not exclude in advance the presence or additional possibility of one or more other features, numbers, steps, operations, elements, or components or a combination thereof.

It will be understood that the terms “connected to” or “coupled to” or “contacting” may include a physical and/or electrical connection or coupling or contact.

Unless otherwise defined, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

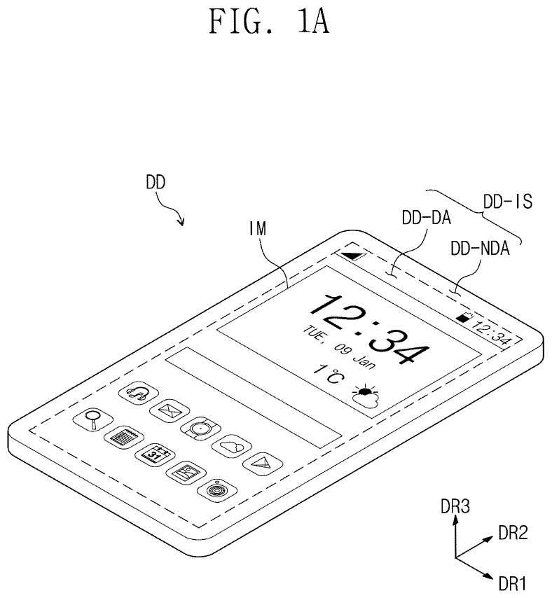

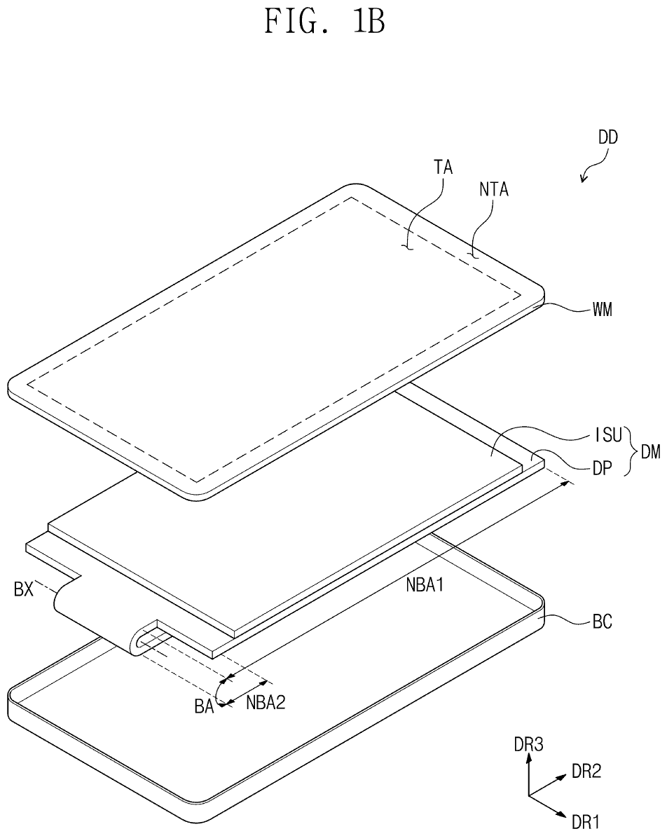

FIG. 1A is a schematic perspective view of a display device according to an embodiment of the disclosure, and FIG. 1B is an exploded schematic perspective view of the display device according to an embodiment of the disclosure.

In the specification, a mobile phone terminal is illustrated as a display device DD. The display device DD according to the disclosure may be applied to small and medium-sized electronic devices such as tablet computers, vehicle navigation systems, game consoles, and smart watches as well as large-sized electronic devices such as televisions and monitors.

Referring to FIGS. 1A and 1B, the display device DD may display an image IM through a display surface DD-IS. Icon images are illustrated as examples of the image IM. The display surface DD-IS may be parallel to a plane defined by a first direction DR1 and a second direction DR2. A normal direction of the display surface DD-IS, that is, a thickness direction of the display device DD, may be parallel to a third direction DR3.

The display surface DD-IS may include a display area DD-DA on which the image IM is displayed and a non-display area DD-NDA adjacent to the display area DD-DA. The non-display area DD-NDA may be an area on which the image IM is not displayed. However, the disclosure is not limited thereto, and the non-display area DD-NDA may be adjacent to one side of the display area DD-DA or may be omitted.

The meaning of “in plan view” may mean when viewed in the third direction DR3. Front surfaces (or upper surfaces) and rear surfaces (or lower surfaces) of layers or units, which will be described below, may be distinguished by the third direction DR3. However, the disclosure is not limited thereto, and a combination of the first to third directions DR1, DR2, and DR3 may be changed to another combination.

Further, the display device DD may include a window WM, a display module DM, and a storage member BC. Although not illustrated, the display device DD may further include an optical member disposed between the window WM and the display module DM. The optical member may include a polarizer.

The window WM may be disposed on the display module DM and transmit an image provided from the display module DM to the outside. The window WM may include a transmissive area TA and a non-transmissive area NTA. The transmissive area TA may overlap the display area DD-DA and have a shape corresponding to the display area DD-DA. The window WM may include a base layer and functional layers arranged on the base layer. The functional layers may include a protective layer, a fingerprint preventing layer, and the like. The base layer of the window WM may be made of glass, sapphire, or plastic.

The non-transmissive area NTA may overlap the non-display area DD-NDA and have a shape corresponding to the non-display area DD-NDA. The non-transmissive area NTA may be an area having a relatively low light transmittance as compared to the transmissive area TA. The non-transmissive area NTA may be defined by arranging a bezel pattern in a partial area of the base layer of the window WM, and an area in which the bezel pattern is not disposed may be defined as the transmissive area TA. However, the technical spirit of the disclosure is not limited thereto, and the non-transmissive area NTA may be omitted.

According to an embodiment of the disclosure, a display panel DP may be a liquid crystal display panel, an electrophoretic display panel, a microelectromechanical system display panel, an electrowetting display panel, an organic light emitting display panel, an inorganic light emitting display panel, or a quantum dot light emitting display panel, and the disclosure is not limited thereto. Hereinafter, the display panel DP may be described as the organic light emitting display panel.

An input sensor ISU may include a capacitive sensor, an optical sensor, an ultrasonic sensor, or an electromagnetic induction sensor. The input sensor ISU may be formed on the display panel DP through a continuous process or may be separately manufactured and attached to an upper portion of the display panel DP through an adhesive layer, and the disclosure is not limited to any one particular embodiment.

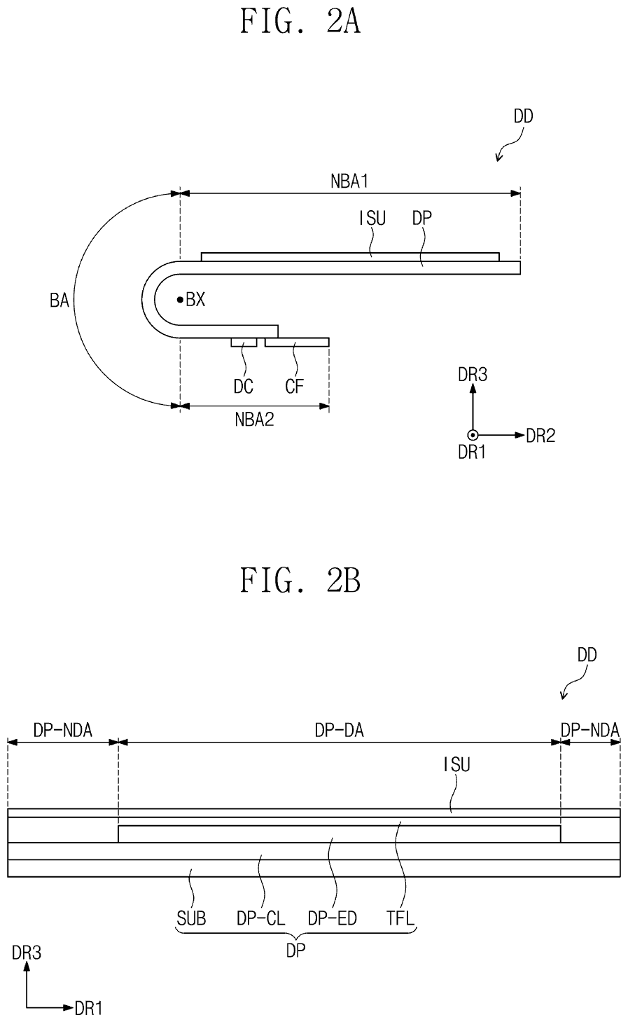

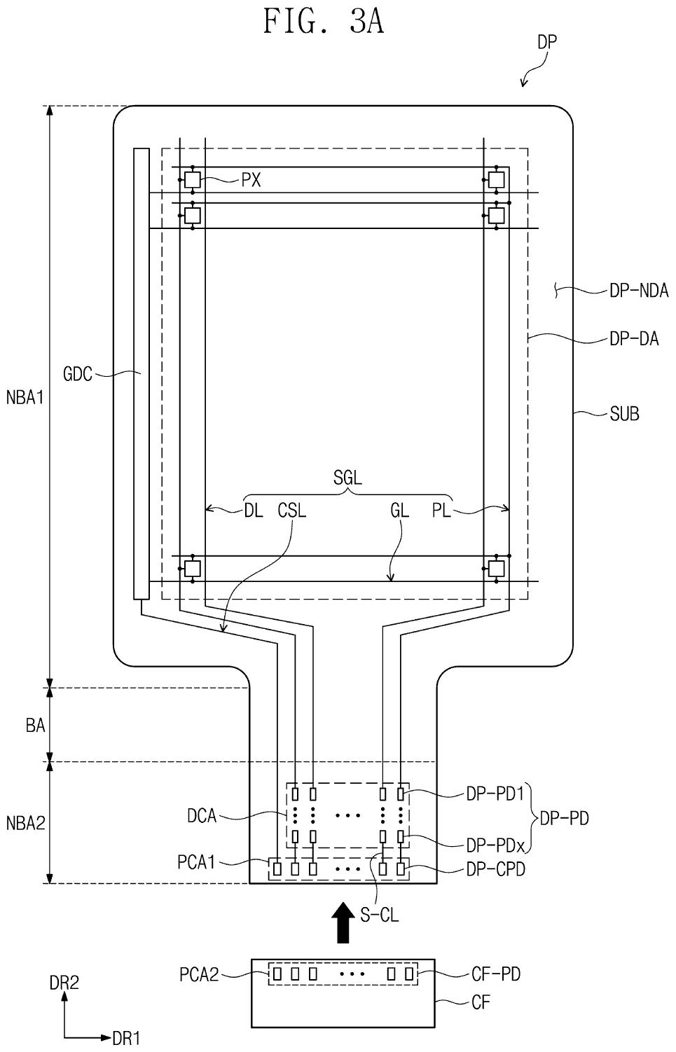

FIGS. 2A and 2B are schematic cross-sectional views of the display device according to an embodiment of the disclosure.

Referring to FIG. 2A, the display device DD according to an embodiment may include a driving chip DC and a circuit board CF. Although an embodiment in which the driving chip DC is mounted on the display panel DP is illustrated, the disclosure is not limited thereto. The driving chip DC may generate a driving signal required for operation of the display panel DP based on a control signal transmitted from the circuit board CF.

The circuit board CF may be disposed on a rear surface of the display panel DP due to the driving chip DC electrically bonded to the display panel DP. The storage member BC (see FIG. 1B) may accommodate the display device DD and may be coupled to the window WM (see FIG. 1B). The circuit board CF may be disposed at an end of a base substrate SUB and electrically connected to a circuit element layer DP-CL. Although not illustrated, the electronic device may further include a main board, electronic modules mounted on the main board, a camera module, a power module, and the like.

The display panel DP according to an embodiment may include a bending area BA and a first non-bending area NBA1 and a second non-bending area NBA2 spaced apart from each other in the third direction DR3 with the bending area BA interposed therebetween.

The bending area BA may be defined as an area in which the display panel DP is bent along a virtual bending axis BX extending in the first direction DR1. The first non-bending area NBA1 may be defined as an area overlapping the transmissive area TA (see FIG. 1B), and the second non-bending area NBA2 may be defined as an area to which the circuit board CF is connected.

In case that the bending area BA is bent with respect to the bending axis BX, the circuit board CF and the driving chip DC may be bent in a direction toward the rear surface of the display panel DP and arranged on the rear surface of the display panel DP. In case that the bending area BA is bent with respect to the bending axis BX, the first non-bending area NBA1 and the second non-bending area NBA2 may be spaced apart from each other in the third direction DR3.

Although not illustrated, additional components may be arranged to compensate for a step difference between the circuit board CF and the rear surface of the display panel DP, which is caused by the bending area BA.

According to an embodiment of the disclosure, a width of the first non-bending area NBA1 in the first direction DR1 may be greater than widths of the bending area BA and the second non-bending area NBA2. However, the disclosure is not limited thereto. The width of the bending area BA in the first direction DR1 may be provided in a shape that becomes narrower from the first non-bending area NBA1 to the second non-bending area NBA2. The disclosure is not limited to any one particular embodiment.

Referring to FIG. 2B, the display panel DP may include the base substrate SUB, the circuit element layer DP-CL disposed on the base substrate SUB, a display element layer DP-ED, and an upper insulating layer TFL. The input sensor ISU may be disposed on the upper insulating layer TFL.

In FIG. 2B, an area corresponding to the bending area BA and the second non-bending area NBA2 of the display panel DP described above in FIG. 2A is omitted.

The display panel DP may include a display area DP-DA and a non-display area DP-NDA. The display area DP-DA of the display panel DP may correspond to the display area DD-DA (see FIG. 1A) illustrated in FIG. 1A or the transmissive area TA (see FIG. 1B) illustrated in FIG. 1B, and the non-display area DP-NDA may correspond to the non-display area DD-NDA (see FIG. 1A) illustrated in FIG. 1A or the non-transmissive area NTA (see FIG. 1B) illustrated in FIG. 1B.

The base substrate SUB may include at least one plastic film. The base substrate SUB may be a flexible substrate and may include a plastic substrate, a glass substrate, a metal substrate, or an organic/inorganic composite material substrate.

The display element layer DP-ED may include multiple organic light emitting diodes. The display element layer DP-ED may further include an organic layer such as a pixel defining film. The upper insulating layer TFL may seal the display element layer DP-ED. For example, the upper insulating layer TFL may include a thin film encapsulation layer. The thin film encapsulation layer may include a laminated structure of an inorganic layer/organic layer/inorganic layer. The upper insulating layer TFL protects the display element layer DP-ED from foreign substances such as moisture, oxygen, and dust particles. However, the disclosure is not limited thereto, and the upper insulating layer TFL may further include an insulating layer in addition to the thin film encapsulation layer. For example, the upper insulating layer TFL may further include an optical insulating layer for controlling a refractive index.

In an embodiment of the disclosure, an encapsulation substrate may be provided instead of the upper insulating layer TFL. The encapsulation substrate may be disposed on the display element layer DP-ED to face the base substrate SUB, and the encapsulation substrate may be rigid compared to the upper insulating layer TFL. The encapsulation substrate may seal the display element layer DP-ED, and at the same time, may protect the display element layer DP-ED from an external impact.

The input sensor ISU may be directly disposed on the display panel DP. In the specification, the wording “component A is directly disposed on component B” means that no adhesive layer is disposed between component A and component B. In an embodiment, the input sensor ISU together with the display panel DP may be manufactured by a continuous process. However, the technical spirit of the disclosure is not limited thereto, and the input sensor ISU may be provided as an individual panel and coupled to the display panel DP through an adhesive layer. As another example, the input sensor ISU may be omitted.

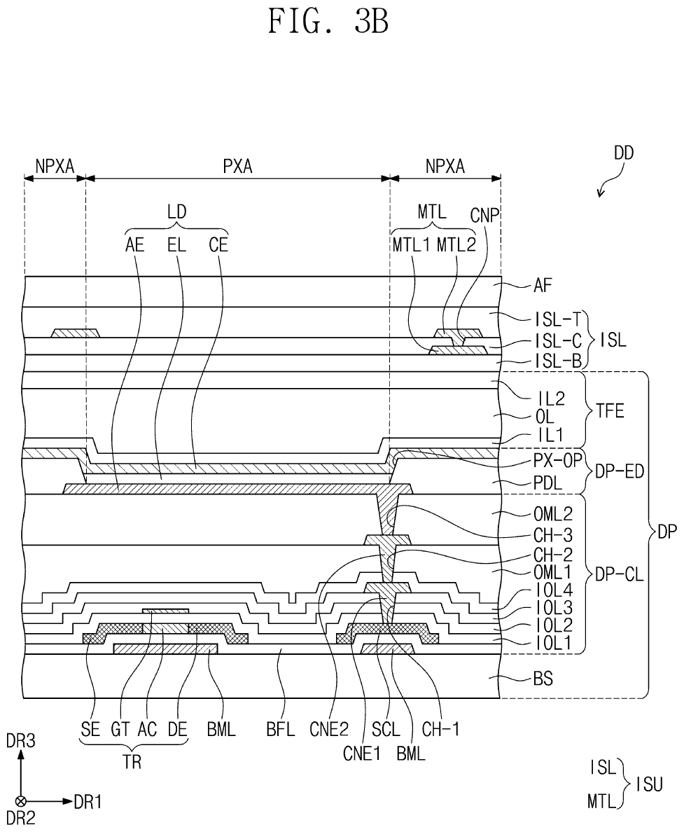

FIG. 3A is a schematic plan view of a display panel according to an embodiment of the disclosure, and FIG. 3B is a schematic cross-sectional view of the display panel according to an embodiment of the disclosure.

Referring to FIG. 3A, the display panel DP may include multiple pixels PX, a gate driving circuit GDC, multiple signal lines SGL, and multiple display pads DP-PD and DP-CPD.

The pixels PX may be arranged in the display area DP-DA. Each of the pixels PX may include an organic light emitting diode and a pixel driving circuit connected thereto. The display area DP-DA may be an area in which the organic light emitting diode is substantially disposed. Thus, the pixel driving circuit may be disposed in the display area DP-DA or may also be disposed in the non-display area DP-NDA. The pixel driving circuit may be disposed at various positions as long as the pixel driving circuit is electrically connected to the organic light emitting diode, and the disclosure is not limited to any one particular embodiment.

The gate driving circuit GDC may sequentially output gate signals to multiple gate lines GL. The gate driving circuit GDC may include multiple thin film transistors formed through the same process as that of the driving circuits of the pixels PX, for example, a low temperature polycrystaline silicon (LTPS) process or a low temperature polycrystalline oxide (LTPO) process. The display panel DP may further include another driving circuit that provides light emitting control signals to the pixels PX.

It is illustrated in an embodiment that the gate driving circuit GDC is disposed in the non-display area DP-NDA, but the disclosure is not limited thereto. For example, at least a portion of the gate driving circuit GDC may be disposed to overlap the display area DP-DA in plan view. Further, it is illustrated in an embodiment that the gate driving circuit GDC is a single circuit, but multiple gate driving circuits GDC may also be provided. The gate driving circuit GDC may be arranged at various positions and provided in various numbers as long as the gate driving circuit GDC is electrically connected to the pixels PX, and the disclosure is not limited to any one particular embodiment.

The signal lines SGL include the gate lines GL, data lines DL, a power line PL, and a control signal line CSL. The gate lines GL are respectively connected to corresponding pixels PX among the pixels PX, and the data lines DL are respectively connected to corresponding pixels PX among the pixels PX. The power line PL is connected to the pixels PX. The control signal line CSL may provide control signals to a scan driving circuit.

The signal lines SGL may overlap the display area DP-DA and the non-display area DP-NDA.

The display panel DP may include display pads. The display pads may include the first display pads DP-PD and the second display pads DP-CPD. According to an embodiment of the disclosure, the first display pads DP-PD and the second display pads DP-CPD may be arranged on the second non-bending area NBA2.

A chip area DCA and a first pad area PCA1 spaced apart from each other may be defined in the non-display area DP-NDA. The chip area DCA may be an area coupled to the driving chip DC (see FIG. 2A) and an area in which the first display pads DP-PD are arranged, and the first pad area PCA1 may be an area connected to the circuit board CF and an area in which the second display pads DP-CPD are arranged. The first display pads DP-PD may be electrically connected to the driving chip DC (see FIG. 2A) and transmit electrical signals received from the driving chip DC to the signal lines SGL.

The first display pads DP-PD include first row display pads DP-PD1 arranged in the first direction DR1 and second to x^{th} display pads DP-PD2-DP-PDx sequentially spaced a predetermined or selected distance from the first row display pads DP-PD1 in the second direction DR2 and arranged in the first direction DR1 (x is a natural number greater than or equal to 2).

The second display pads DP-CPD may be arranged in the first pad area PCA1. The second display pads DP-CPD may be arranged in the first direction DR1. The first display pads DP-PD may be respectively connected to corresponding display pads DP-CPD among the second display pads DP-CPD through bridge signal lines S-CL.

Like the first display pads DP-PD, the second display pads DP-CDP may also include row display pads arranged in the first direction DR1.

The circuit board CF may include circuit pads CF-PD arranged in the first direction DR1. The circuit pads CF-PD may be arranged in a second pad area PCA2 defined in the circuit board CF. The circuit pads CF-PD may be pads connected to the display panel DP.

Further, in case that the second display pads DP-CPD are arranged in the form of row pads arranged in the first direction DR1, the circuit pads CF-PD included in the circuit board CF may also have a form in which the circuit pads CF-PD are arranged in the second display pads DP-CPD in one-to-one correspondence, and the disclosure is not limited to any one particular embodiment. The second pad area PCA2 of the circuit board CF may be disposed on the first pad area PCA1. The second display pads DP-CPD may be electrically connected to the circuit pads CF-PD included in the circuit board CF and transmit electrical signals received from the circuit board CF to the first display pads DP-PD. The circuit board CF may be rigid or flexible. For example, in case that the circuit board CF is flexible, the circuit board CF may be provided as a flexible printed circuit board.

The circuit board CF may include a timing control circuit that controls an operation of the display panel DP. The timing control circuit may be mounted on the circuit board CF in the form of an integrated chip. Further, although not illustrated, the circuit board CF may include an input sensing circuit that controls the input sensor ISU.

It is described that the display panel DP includes the first display pads DP-PD for mounting the driving chip DC (see FIG. 2A) illustrated in FIG. 2A, but the disclosure is not limited thereto. The driving chip DC (see FIG. 2A) may be mounted on the circuit board CF, and in this case, the first display pads DP-PD may be omitted.

FIG. 3B illustratively illustrates a cross section of the display device DD in a portion including the one pixel PX (see FIG. 3A) illustrated in FIG. 3A. The display device DD may include the display panel DP and the input sensor ISU (see FIG. 2B), and the display panel DP may include a base layer BS, a circuit layer DP-CL, a display element layer DP-ED, and an encapsulation layer TFE. The one pixel PX (FIG. 3A) may have an equivalent circuit including multiple transistors, one capacitor, and a light emitting element, and the equivalent circuit of the pixel PX may be modified into various forms. FIG. 3B illustratively illustrates one transistor TR and one light emitting element LD included in the pixel PX (see FIG. 3A).

The display panel DP according to one embodiment may include multiple insulating layers, a transistor, a conductive pattern, a signal wiring line, and the like.

Multiple inorganic films, multiple organic films, a semiconductor layer, and a conductive layer may be formed in manners such as coating or deposition. Thereafter, the inorganic films, the organic films, the semiconductor layer, and the conductive layer may be selectively patterned by a photolithography manner. In this way, the circuit layer DP-CL including the insulating layers formed from the inorganic films and the organic films, the transistor including a semiconductor pattern formed from the semiconductor layer, the conductive pattern and the signal wiring line formed from the conductive layer, and the like may be formed.

Thereafter, the display element layer DP-ED including the light emitting element LD including the conductive pattern or the like may be formed on the circuit layer DP-CL, and the encapsulation layer TFE covering the display element layer DP-ED may be formed on the circuit layer DP-CL.

Referring to FIG. 3B, the circuit layer DP-CL may include a shielding electrode BML, a buffer layer BFL, multiple insulating layers IOL1, IOL2, IOL3, and IOL4 including inorganic films, multiple insulating layers OML1 and OML2 including organic films, the transistor TR, connection electrodes CNE1 and CNE2, a signal wiring line SCL, and the like.

The shielding electrode BML may be disposed on the base layer BS. The shielding electrode BML may overlap the transistor TR. Further, in an embodiment, the shielding electrode BML may be disposed even under the signal wiring line SCL. The shielding electrode BML may shield a light input from a lower portion of the display panel DP to the transistor TR or the signal wiring line SCL so as to protect the semiconductor pattern or the conductive pattern such as the transistor TR and the signal wiring line SCL. The shielding electrode BML may include a conductive material. In an embodiment, the shielding electrode BML may be connected to the power line PL (FIG. 3A) to receive a voltage. In case that a voltage is applied to the shielding electrode BML, a threshold voltage of the transistor TR disposed on the shielding electrode BML may be maintained. The disclosure is not limited thereto, and the shielding electrode BML may be a floating electrode. In an embodiment, the shielding electrode BML may be omitted.

The buffer layer BFL may be disposed on the base layer BS to cover the shielding electrode BML. The buffer layer BFL may improve a coupling force between the base layer BS and the semiconductor pattern or the conductive pattern disposed on the buffer layer BFL. Further, the buffer layer BFL may prevent metal atoms or impurities from being diffused from the base layer BS to the semiconductor pattern or the conductor pattern.

The buffer layer BFL may be an inorganic film. The buffer layer BFL may include at least one of a silicon oxide, a silicon nitride, and a silicon oxy nitride. For example, the buffer layer BFL may include a structure in which silicon oxide layers and silicon nitride layers are alternately laminated.

The transistor TR may include a source SE, a channel AC, a drain DE, and a gate GT. The source SE, the channel AC, and the drain DE of the transistor TR may be formed from the semiconductor pattern. The source SE and the drain DE may extend from the channel AC in opposite directions on a cross section. Further, FIG. 3 illustrates a portion of the signal wiring line SCL formed from the semiconductor pattern. Although not separately illustrated, the signal wiring line SCL may be connected to the drain DE of the transistor TR in plan view.

The semiconductor pattern of the transistor TR may include polysilicon, amorphous silicon, or metal oxide and is not limited to any one thereof as long as a material has semiconductor properties.

The semiconductor pattern may include multiple areas divided according to a magnitude of conductivity. An area of the semiconductor pattern, which is doped with a dopant or reduced with a metal oxide may have high conductivity and may substantially serve as a source electrode or a drain electrode of the transistor TR. An area of the semiconductor pattern, which has high conductivity, may correspond to the source SE and the drain DE of the transistor TR. An area that is undoped or doped at a low concentration or has low conductivity due to a non-reduced metal oxide may correspond to the channel AC (or an active area) of the transistor TR.

The first insulating layer IOL1 may cover the semiconductor pattern of the transistor TR and may be disposed on the buffer layer BFL. The gate GT of the transistor TR may be disposed on the first insulating layer IOL1. The gate GT may overlap the channel AC of the transistor TR. In an embodiment, the gate GT may function as a mask in a process of doping the semiconductor pattern of the transistor TR.

The gate GT may include titanium (Ti), silver (Ag), an alloy containing silver, molybdenum (Mo), an alloy containing molybdenum, aluminum (Al), an alloy containing aluminum, aluminum nitride (AlN), tungsten (W), tungsten nitride (WN), copper (Cu), indium tin oxide (ITO), indium zinc oxide (IZO) or the like, but the disclosure is not particularly limited thereto.

The first insulating layer IOL1 may include an inorganic film. The first insulating layer IOL1 may be referred to as a first inorganic film. For example, the first insulating layer IOL1 may be an inorganic film including at least one of an aluminum oxide, a titanium oxide, a silicon oxide, a silicon nitride, a silicon oxy nitride, a zirconium oxide, and a hafnium oxide. The first insulating layer IOL1 may have a single-layer structure or a multi-layer structure. The first insulating layer IOL1 may have a structure in which the inorganic films are laminated. In case that the first insulating layer IOL1 has a structure in which multiple layers are laminated, the first insulating layer IOL1 may further include a buffer inorganic film that is disposed directly under the inorganic film and has a relatively high O content compared to the adjacent inorganic film. The buffer inorganic film may have physical properties that are similar to those of a buffer insulating layer of the input sensor ISU.

Further, in an embodiment, the first insulating layer IOL1 may further include an organic film in addition to the inorganic film. In case that the first insulating layer IOL1 includes a structure in which the inorganic film and the organic film are laminated, the first insulating layer IOL1 may further include a buffer inorganic film disposed between the inorganic film and the organic film adjacent to each other. Even in this case, the buffer inorganic film may have physical properties similar to those of the buffer insulating layer of the input sensor ISU. For example, the buffer inorganic film may contain relatively high contents of O elements and C elements compared to the adjacent inorganic film.

The multi-layer structure described in the first insulating layer IOL1 may also be introduced to the second to fourth insulating layers IOL2, IOL3, and IOL4, which will be described below. Accordingly, the laminated structure of the insulating layer having the multi-layer structure, the buffer inorganic film in the multi-layer structure, and the like, which are described above, may be equally applied to the second to fourth insulating layers IOL2, IOL3, and IOL4, which will be described below.

The second insulating layer IOL2 may be disposed on the first insulating layer IOL1 and cover the gate GT. The second insulating layer IOL2 may commonly overlap the pixels PX. The second insulating layer IOL2 may include an inorganic film. The second insulating layer IOL2 may be referred to as a second inorganic film. For example, the second insulating layer IOL2 may include at least one of a silicon oxide, a silicon nitride, and a silicon oxy nitride. The second insulating layer IOL2 may be an inorganic layer and/or an organic layer and may have a single-layer structure or a multi-layer structure. In an embodiment, the second insulating layer IOL2 may have a multilayer structure including a silicon oxide layer and a silicon nitride layer.

The third insulating layer IOL3 may be disposed on the second insulating layer IOL2. The third insulating layer IOL3 may include an inorganic film. The third insulating layer IOL3 may be referred to as a third inorganic film. The third insulating layer IOL3 may have a single-layer structure or a multi-layer structure. For example, the third insulating layer IOL3 may have a multi-layer structure including a silicon oxide layer and a silicon nitride layer.

The first connection electrode CNE1 may be disposed on the third insulating layer IOL3. The first connection electrode CNE1 may be connected to the signal wiring line SCL through a first contact hole CH-1 passing through the first insulating layer IOL1, the second insulating layer IOL2, and the third insulating layer IOL3.

The fourth insulating layer IOL4 may be disposed on the third insulating layer IOL3. The fourth insulating layer IOL4 may include an inorganic film, and the fourth insulating layer IOL4 may also be referred to as a fourth inorganic film. The fourth insulating layer IOL4 may be a single-layer silicon oxide layer.

The fifth insulating layer OML1 may be disposed on the fourth insulating layer IOL4. The fifth insulating layer OML1 may include an organic film. The fifth insulating layer OML1 may be referred to as a first organic film. The first organic film may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin.

The second connection electrode CNE2 may be disposed on the fifth insulating layer OML1. The second connection electrode CNE2 may be connected to the first connection electrode CNE1 through a second contact hole CH-2 passing through the fourth insulating layer IOL4 and the fifth insulating layer OML1.

The sixth insulating layer OML2 may be disposed on the fifth insulating layer OML1 and cover the second connection electrode CNE2. The sixth insulating layer OML2 may include an organic film. The sixth insulating layer OML2 may be referred to as a second organic film. The second organic film may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin.

Although not illustrated in FIG. 3B, the circuit layer may further include multiple transistors and may further include signal wiring lines electrically connected to the transistors. The signal wiring lines may extend to be connected to the first display pads DP-PD of the non-display area DP-NDA (see FIG. 3A). Further, the signal wiring lines may extend to be connected to sensing pads of a non-sensing area.

The display element layer DP-ED is disposed on the circuit layer DP-CL. The display element layer DP-ED may include a pixel defining film PDL and the light emitting element LD. The light emitting element LD may include a first electrode AE, a light emitting layer EL, and a second electrode CE.

The first electrode AE may be disposed on the sixth insulating layer OML2. The first electrode AE may be connected to the second connection electrode CNE2 through a third contact hole CH-3 passing through the sixth insulating layer OML2. The first electrode AE may be electrically connected to the drain DE of the transistor TR through the first and second connection electrodes CNE1 and CNE2.

The first electrode AE may be referred to as a pixel electrode. The first electrode AE may be formed of a metal material, a metal alloy, or a conductive compound. The first electrode AE may be an anode or a cathode. The first electrode AE may be a transmissive electrode, a semi-transmissive electrode or a reflective electrode. In case that the first electrode AE is the transmissive electrode, the first electrode AE may include a transparent metal oxide, for example, an indium tin oxide (ITO), an indium zinc oxide (IZO), a zinc oxide (ZnO), an indium tin zinc oxide (ITZO) or the like. In case that the first electrode AE is the semi-transmissive electrode or the reflective electrode, the first electrode AE may include Ag, Mg, Cu, Al, Pt, Pd, Au, Ni, Nd, Ir, Cr, Li, Ca, LiF/Ca, LiF/Al, Mo, Ti, W, or compounds or mixtures thereof (e.g., a mixture of Ag and Mg). In other embodiments, the first electrode AE may include a multi-layer structure including a reflective film or a semi-transmissive film formed of the above materials and a transparent conductive film formed of an indium tin oxide (ITO), an indium zinc oxide (IZO), a zinc oxide (ZnO), an indium tin zinc oxide (ITZO) or the like. For example, the first electrode AE may have a three-layer structure of ITO/Ag/ITO, but the disclosure is not limited thereto. Further, an embodiment is not limited thereto, and the first electrode AE may include the above-described metal materials, combinations of two or more types of metal materials selected from the above-described metal materials, oxides of the above-described metal materials, or the like.

The pixel defining film PDL may be disposed on the sixth insulating layer OML2. In an embodiment, the pixel defining film PDL may be formed of a polymer resin. For example, the pixel defining film PDL may include a polyacrylate-based resin or a polyimide-based resin. Further, the pixel defining film PDL may be formed to further include an inorganic material in addition to the polymer resin. The pixel defining film PDL may include a light-absorbing material or include black pigment or black dye. The pixel defining film PDL including black pigment or black dye may implement a black pixel defining film. In case that the pixel defining film PDL is formed, carbon black or the like may be used as black pigment or black dye, but an embodiment is not limited thereto.

Further, the pixel defining film PDL may be formed of an inorganic material. For example, the pixel defining film PDL may include a silicon nitride, a silicon oxide, a silicon oxy nitride, or the like.

A pixel opening PX-OP through which a portion of the first electrode AE is exposed may be defined by the pixel defining film PDL. In the display device DD of an embodiment, light emitting areas PXA may be divided by the pixel defining film PDL. The display device DD may include the light emitting areas PXA and a non-light emitting area NPXA, and the non-light emitting area NPXA may be a portion that overlaps the pixel defining film PDL. A portion corresponding to the first electrode AE exposed through the pixel opening PX-OP may be defined as the light emitting area PXA.

In the light emitting element LD, the light emitting layer EL may be disposed on the first electrode AE. In an embodiment, the light emitting layer EL may emit a light having at least one color among blue, red, and green. In an embodiment, the light emitting layer EL may provide a blue light throughout the display area DP-DA (see FIG. 3A).

The second electrode CE may be disposed on the light emitting layer EL. The second electrode CE may have an integral shape and may be commonly disposed in the pixels PX (see FIG. 3A). The second electrode CE may be referred to as a common electrode. The second electrode CE may be a cathode or an anode. For example, in case that the first electrode AE is the anode, the second electrode CE may be the cathode, or in case that the first electrode AE is the cathode, the second electrode CE may be the anode.

The second electrode CE may be a transmissive electrode, a semi-transmissive electrode, or a reflective electrode. In case that the second electrode CE is the transmissive electrode, the second electrode CE may be made of a transparent metal oxide, for example, an indium tin oxide (ITO), an indium zinc oxide (IZO), a zinc oxide (ZnO), an indium tin zinc oxide (ITZO) or the like. Further, the second electrode CE may include Ag, Mg, Cu, Al, Pt, Pd, Au, Ni, Nd, Ir, Cr, Li, Ca, LiF/Ca, LiF/Al, Mo, Ti, W, or compounds or mixtures thereof (e.g., a mixture of Ag and Mg).

Although not illustrated, a hole control layer may be disposed between the first electrode AE and the light emitting layer EL. The hole control layer may include a hole transport layer and may further include a hole injection layer. An electron control layer may be disposed between the light emitting layer EL and the second electrode CE. The electron control layer may include an electron transport layer and may further include an electron injection layer. The hole control layer and the electron control layer may be commonly formed in the pixels PX (FIG. 3A) using an open mask.

The encapsulation layer TFE may be disposed on the display element layer DP-ED. The encapsulation layer TFE may include a first inorganic layer IL1, an organic layer OL, and a second inorganic layer IL2 that are sequentially laminated. However, the layers constituting the encapsulation layer TFE are not limited thereto.

The inorganic layers IL1 and IL2 may protect the display element layer DP-ED from moisture and oxygen, and the organic layer OL may protect the display element layer DP-ED from foreign substances such as dust particles. The inorganic layers IL1 and IL2 may include at least one of a silicon nitride, a silicon oxy nitride, a silicon oxide, a titanium oxide, and an aluminum oxide. The organic layer OL may include an acryl-based organic material. However, the types of materials constituting the inorganic layers IL1 and IL2 and the organic layer OL are not limited thereto.

The input sensor ISU may be disposed on the encapsulation layer TFE. The input sensor ISU may be referred to as a sensor layer, an input sensing layer, or an input sensing panel. The input sensor ISU may include multiple sensor insulating layers ISL and multiple sensor-conductive layers MTL. Among the sensor insulating layers ISL, some sensor insulating layer ISL-B may be directly disposed on the display panel DP. For example, in an embodiment, the input sensor ISU may include a first sensor insulating layer ISL-B, a first sensor-conductive layer MTL1, a second sensor insulating layer ISL-C, a second sensor-conductive layer MTL2, and a third sensor insulating layer ISL-T, which are sequentially laminated on the display panel DP in the third direction DR3.

The first sensor insulating layer ISL-B may include a base insulating layer. Further, the first sensor insulating layer ISL-B may include a buffer insulating layer. For example, the input sensor ISU may be a single layer including only the base insulating layer or the buffer insulating layer or may be a laminated structure including the buffer insulating layer and the base insulating layer, and the disclosure is not limited to any one particular embodiment.

The first sensor-conductive layer MTL1 and the second sensor-conductive layer MTL2 may have a multi-layer structure. The sensor-conductive layer having the multi-layer structure may be a laminate of two or more transparent conductive layers and/or metal layers. For example, the sensor-conductive layer having the multi-layer structure may have a structure in which a transparent conductive layer and a metal layer are laminated or a structure in which metal layers including different metals are laminated.

Examples of the transparent conductive layers included in the first sensor-conductive layer MTL1 and the second sensor-conductive layer MTL2 may include an indium tin oxide (ITO), an indium zinc oxide (IZO), a zinc oxide (ZnO), an indium tin zinc oxide (ITZO), poly(3,4-ethylenedioxythiophene) (PEDOT), metal nanowire, graphene, or the like. The metal layers included in the first sensor-conductive layer MTL1 and the second sensor-conductive layer MTL2 may include molybdenum, silver, titanium, copper, aluminum, or alloys thereof.

The first sensor-conductive layer MTL1 and the second sensor-conductive layer MTL2 may include sensing electrodes of the input sensor ISU and may further include sensing wiring lines.

The second sensor insulating layer ISL-C may be disposed on the first sensor-conductive layer MTL1. The third sensor insulating layer ISL-T may be disposed on the second sensor-conductive layer MTL2. The first sensor-conductive layer MTP1 may be connected to the second sensor-conductive layer MTP2 through contact hole CNT. Each of the second sensor insulating layer ISL-C and the third sensor insulating layer ISL-T may include an inorganic film. Further, each of the second sensor insulating layer ISL-C and the third sensor insulating layer ISL-T may further include an organic film.

Each of the first sensor insulating layer ISL-B, the second sensor insulating layer ISL-C, and the third sensor insulating layer ISL-T may include at least one of a silicon nitride (SiN_{X}) and a silicon oxy nitride (SiO_{X}N_{Y}). Further, the first sensor insulating layer ISL-B, the second sensor insulating layer ISL-C, and the third sensor insulating layer ISL-T may include a silicon oxide (SiO_{X}). The first sensor insulating layer ISL-B, the second sensor insulating layer ISL-C, and the third sensor insulating layer ISL-T may be inorganic films and may include at least one of an aluminum oxide, a titanium oxide, a zirconium oxide, and a hafnium oxide. In the expressions of a silicon nitride (SiN_{X}), a silicon oxynitride (SiO_{X}N_{Y}), and a silicon oxide (SiO_{X}), X and Y may each be greater than 0.

In case that the first sensor insulating layer ISL-B, the second sensor insulating layer ISL-C, and the third sensor insulating layer ISL-T include an organic layer, the organic film may include at least one of an acryl-based resin, a methacrylate-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin.

It is illustrated in FIG. 3B that the input sensor ISU includes the first sensor-conductive layer MTL1 and the second sensor-conductive layer MTL2 that are laminated, but an embodiment is not limited thereto. For example, in an embodiment, the input sensor ISU may include one sensor-conductive layer MTL disposed on the first sensor insulating layer ISL-B. One of the second sensor insulating layer ISL-C and the third sensor insulating layer ISL-T may be omitted.

In FIG. 3B, for a schematic representation of the laminated structure, the first sensor-conductive layer MTL1 and the second sensor-conductive layer MTL2 are illustrated as one layer that overlaps the entire display panel DP, but an embodiment is not limited thereto. Each of the first sensor-conductive layer MTL1 and the second sensor-conductive layer MTL2 may be patterned.

According to an embodiment, the display device DD may include an optical layer. In an embodiment, an optical layer AF may be directly disposed on the third sensor insulating layer ISL-T. However, the disclosure is not limited thereto, an adhesive layer or the like may be further included between the optical layer AF and the input sensor ISU, and the disclosure is not limited to any one particular embodiment.

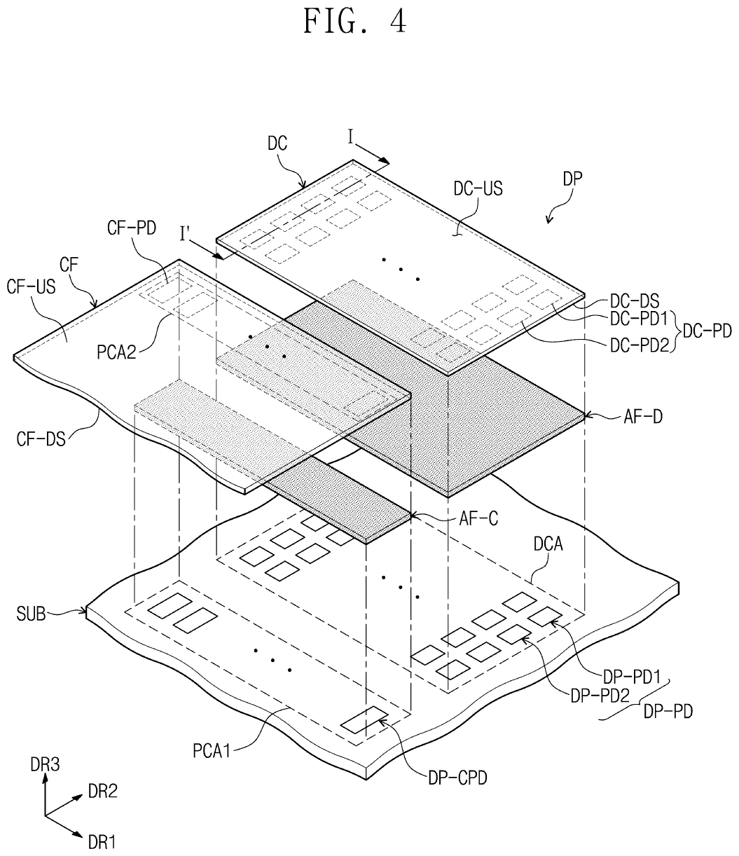

FIG. 4 is an exploded schematic perspective view of a bonding area of the display device according to an embodiment of the disclosure.

Referring to FIG. 4, the display panel DP includes a first adhesive layer AF-C disposed between the circuit board CF and the base substrate SUB and a second adhesive layer AF-D disposed between the driving chip DC and the base substrate SUB. The first adhesive layer AF-C may connect the circuit board CF and the display panel DP, and the second adhesive layer AF-D may connect the driving chip DC and the display panel DP. Each of the first adhesive layer AF-C and the second adhesive layer AF-D may have insulating properties. The first adhesive layer AF-C and the second adhesive layer AF-D physically couple the circuit board CF and the driving chip DC to the display panel DP.

The circuit board CF includes an upper surface CF-US and a lower surface CF-DS. The lower surface CF-DS of the circuit board CF may be a surface facing the display panel DP. The circuit pads CF-PD may be arranged on the lower surface CF-DS of the circuit board CF and electrically connected to the second display pads DP-CPD of the display panel DP.

The driving chip DC includes an upper surface DC-US and a lower surface DC-DS. The lower surface DC-DS of the driving chip DC may be a surface facing the display panel DP. The driving chip DC includes chip pads DC-PD arranged on the lower surface DC-DS. The chip pads DC-PD may be electrically connected to the first display pads DP-PD arranged on the base substrate SUB.

The chip pads DC-PD may include first row chip pads DC-PD1 arranged in the first direction DR1, second row chip pads DC-PD2 spaced apart from the first row chip pads DC-PD1 in the second direction DR2, and n^{th} chip pads spaced apart from the second row chip pads DC-PD2 in the second direction DR2 (n is a natural number greater than or equal to 3). The first row chip pads DC-PD1 and the second row chip pads DC-PD2 may have a shape exposed from a lower surface of the driving chip DC to the outside.

It is illustrated in FIG. 4 that the chip pads DC-PD are arranged in four rows, but the disclosure is not limited thereto, and the chip pads DC-PD may be arranged in five or more rows based on a structure in which the first display pads DP-PD are arranged.

The connection between the circuit board CF and the display panel DP is illustrated below as an example, but the connection structure between the circuit board CF and the display panel DP, which will be described below, may be applied to the connection between the driving chip DC and the display panel DP.

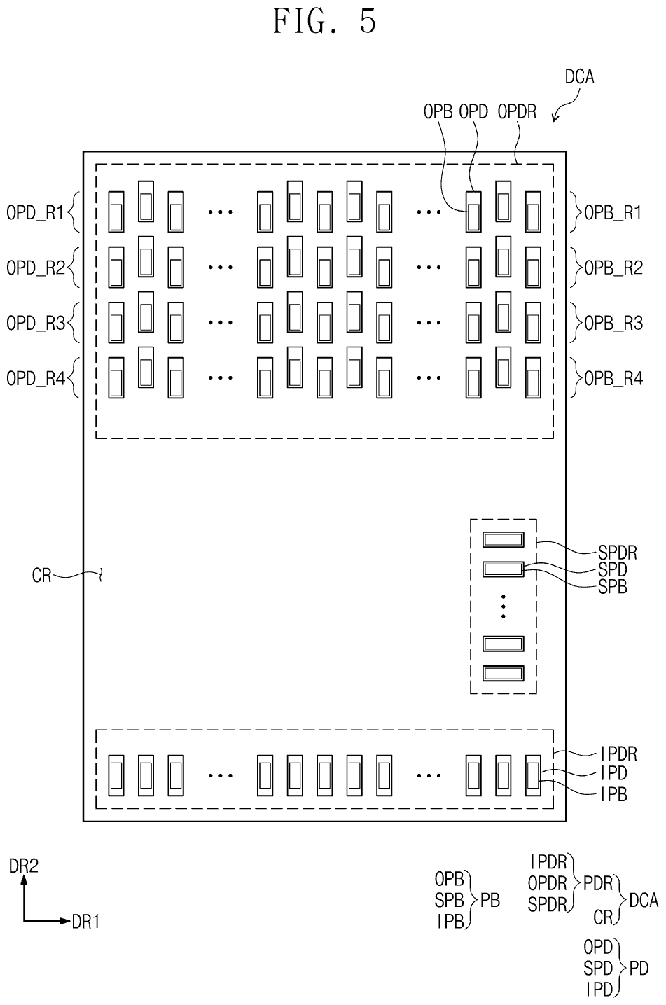

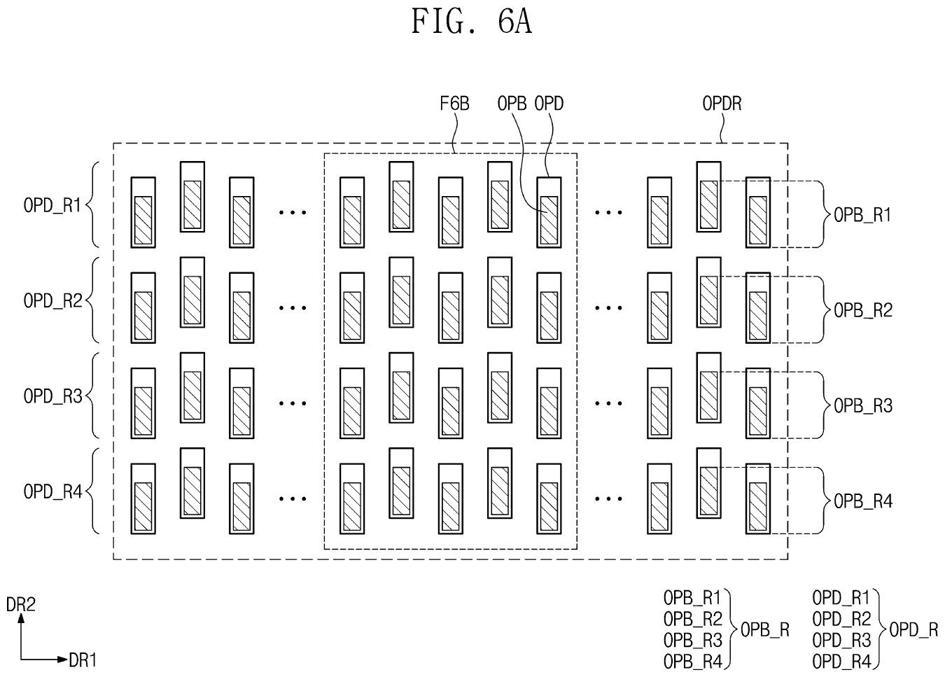

Further, pads PD (see FIG. 5), which will be described below, may correspond to the first display pads DP-PD (see FIG. 4), and bumps PB (see FIG. 5) may correspond to the chip pads DC-PD.

FIG. 5 is a schematic plan view of a chip area of the display device according to an embodiment of the disclosure.

Referring to FIG. 5, the display panel DP may include the chip area DCA. The chip area DCA may include a pad area PDR in which the pads PD of an input pad part IPDR, a side pad part SPDR, and an output pad part OPDR are arranged and a circuit area CR in which circuits are arranged.

Each of the input pad part IPDR, the side pad part SPDR, and the output pad part OPDR may include the pads PD.

The output pad part OPDR includes multiple output pads OPD, the input pad part IPDR includes multiple input pads IPD, and the side pad part SPDR includes multiple side pads SPD.

The driving chip DC (see FIG. 4) may include multiple output bumps OPB corresponding to the output pads OPD, multiple input bumps IPB corresponding to the input pads IPD, and side bumps SPB corresponding to the side pads SPD. The output bumps OPB may overlap the output pads OPD, the input bumps IPB may overlap the input pads IPD, and the side bumps SPB may overlap the side pads SPD.

The input pads IPD may be arranged in the first direction DR1 and constitute a row. The side pads SPD may be arranged in the second direction DR2 and constitute a column. The input bumps IPB may be arranged to correspond to the input pads IPD, and the side bumps SPB may be arranged to correspond to the side pads SPD.

The arrangement of the input pads IPD and the side pads SPD illustrated in the drawings is illustrative, the disclosure is not limited to the illustration of the drawings corresponding to the design of the display panel DP or the driving chip DC, the arrangement of the input pads IPD and the side pads SPD may be different, and the disclosure is not limited to any one particular embodiment.

Various signals provided from outside the display device DD (see FIG. 1B) may be provided to the input pad part IPDR and the side pad part SPDR. The various signals may be provided to the driving chip DC through the input bumps IPB arranged to correspond to the input pad part IPDR and the side bumps SPB arranged to correspond to the side pad part SPDR.

The output pad part OPDR may include the output pads OPD. The output pads OPD may be arranged in the first direction DR1 and the second direction DR2. Each of the output pads OPD arranged in the first direction DR1 may be defined as an output pad row. Each of output pad rows OPD_R1, OPD-R2, OPD_R3, and OPD_R4 may be arranged in the second direction DR2.

It is illustrated in the drawings that the output pad part OPDR includes only the first to fourth output pad rows OPD_R1, OPD_R2, OPD_R3, and OPD_R4, but the disclosure is not limited thereto, the output pad part OPDR may include five for more output pad rows, and the disclosure is not limited any one particular embodiment.

The output pad part OPDR may receive various signals output from the driving chip DC (see FIG. 4) through the output bumps OPB arranged to correspond to the output pad part OPDR. The various signals provided to the output pad part OPDR may be provided to each of the pixels PX arranged in the display area through multiple lines connected to the output pad part OPDR.

The output pads OPD may be spaced a predetermined or selected distance from each other in the first direction DR1. The signal lines SGL (see FIG. 3) may be arranged in a space between the output pads OPD in the first direction DR1.

To correspond to the number of pixels PX, the output pad part OPDR may include the output pads OPD of which the number is greater than the number of input pads IPD of the input pad part IPDR or the number of side pads SPD of the side pad part SPDR.

The output pads OPD included in the output pad rows OPD_R1, OPD-R2, OPD_R3, and OPD_R4 may have the same shape and may be arranged side by side.

The output pads OPD arranged in the same row may be arranged to be offset from each other in a zigzag shape in the first direction DR1. For example, the output pads OPD arranged in the same row and adjacent to each other may be shifted by a predetermined or selected distance in the second direction DR2 and may be arranged to be partially offset from each other. The shifted predetermined or selected distance may be smaller than a distance between adjacent rows.

The output pads OPD may be arranged in a zigzag shape, so that closeness of the output pads OPD within the same area may be improved, and ultra-miniaturization of the display panel DP (see FIG. 4) may be achieved. In detail, since an area occupied by all the output pads OPD in the second direction DR2 may decrease, ultra-miniaturization of the display panel DP (see FIG. 4) may be achieved. Further, the output bumps OPB may be arranged in a zigzag shape, so that closeness of the output bumps OPB within the same area may be improved, and ultra-miniaturization of the display device DD (see FIG. 2A) may be achieved.

Further, the output pads OPD may be arranged in a zigzag shape, and thus in case that heat and pressure are applied to the driving chip DC (see FIG. 4) so that the output pads OPD and the output bumps OPB are electrically connected, deformation or cracks may be prevented from occurring due to a pressure (or a stress) concentrated in areas adjacent to the output pads OPD. For example, in case that the pressure (or the stress) is applied to the areas adjacent to the output pads OPD, the applied portions are prevented from being arranged with a certain rule in a specific one direction (e.g., the first direction DR1), and thus the pressure (or the stress) may be uniformly distributed throughout the display panel DP (see FIG. 4). Therefore, the entire display panel DP (see FIG. 4) may be prevented from being deformed due to local deformation inside the display panel DP (see FIG. 4).

In the case of an embodiment of the disclosure in which the output pads OPD and the output bumps OPB are arranged in a zigzag shape, the pressure (or the stress) applied to the areas adjacent to the output pads OPD may be reduced by 8% to 13% as compared to a case in which all of the output pads OPD and the output bumps OPB are not arranged in a zigzag shape.

Each of the output bumps OPB arranged to correspond to the output pad part OPDR may be arranged to have a specific pattern. In detail, the output bumps OPB may include output bump rows OPB_R1, OPB-R2, OPB_R3, and OPB_R4 in which the output bumps OPB are arranged in the first direction DR1.

The output bumps OPB included in the output bump rows OPB_R1, OPB-R2, OPB_R3, and OPB_R4 may have the same shape. Further, the output bumps OPB may have a partially symmetrical shape, and the disclosure is not limited to any one particular embodiment.

According to an embodiment of the disclosure, the output bumps OPB arranged in the same row may be arranged to be offset from each other in a zigzag shape in the first direction DR1. For example, the output bumps OPB arranged in the same row and adjacent to each other may be shifted by a predetermined or selected distance in the second direction DR2 and may be arranged to be partially offset from each other. The shifted predetermined or selected distance may be smaller than a distance between adjacent rows.

Cracks or damages that may occur in case that the driving chip DC is mounted may be minimized due to the arrangement of the output pads OPD arranged in a zigzag shape and/or the arrangement of the output bumps OPB arranged in a zigzag shape.

In the case of an embodiment of the disclosure in which the output pads OPD and the output bumps OPB are arranged in a zigzag shape, the pressure (or the stress) applied to the areas adjacent to the output pads OPD may be reduced by 8% to 13% as compared to a case (comparative example) in which all of the output pads OPD and the output bumps OPB are not arranged in a zigzag shape.

Further, in the case of an embodiment of the disclosure, the amount of deformation of the display panel in a thickness direction may be reduced by 22% to 66% as compared to the above-described comparative example.

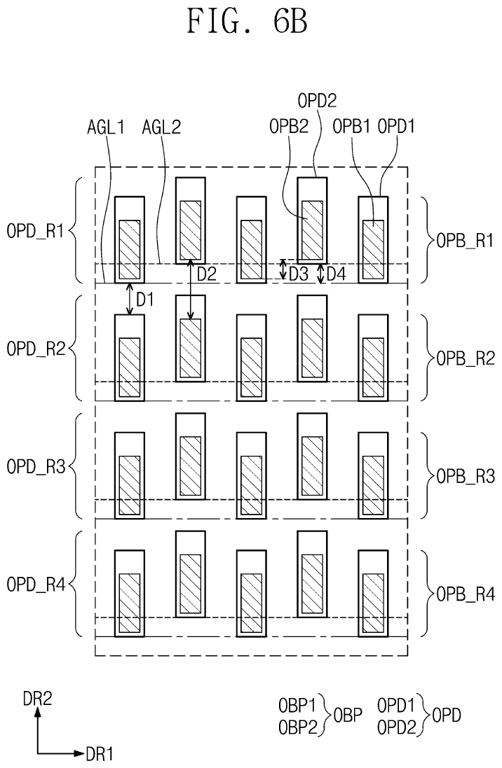

FIGS. 6A and 6B are enlarged schematic views of a portion of the chip area of the display device according to an embodiment of the disclosure. FIG. 6A is an enlarged plan view of the output pad part OPDR of FIG. 5, and FIG. 6B is an enlarged plan view of part F6B of FIG. 6A.

Referring to FIGS. 6A and 6B, each of the output pad rows OPD_R may include multiple first output pads OPD1 and multiple second output pads OPD2. The first output pads OPD1 may be arranged in the first direction DR1. The second output pads OPD2 may be arranged alternately with the first output pads OPD1 in the first direction DR1.

The output pad rows OPD_R may be arranged to be spaced a first distance D1 from each other. The output bump rows OPB_R may be arranged to be spaced a second distance D2 from each other. The second distance D2 may be greater than or equal to the first distance D1. The areas occupied by the output pads OPD and the output bumps OPB in the chip area DCA may be adjusted by adjusting a difference between the first distance D1 and the second distance D2.

The second output pads OPD2 may be arranged to be shifted from the first output pads OPD1 by a fourth distance D4 in the second direction DR2. In detail, in case that the first output pads OPD1 are arranged in the first direction DR1 with respect to a first alignment line AGL1 and the second output pads OPD2 are arranged in the second direction DR2 with respect to a second alignment line AGL2, a distance between the first alignment line AGL1 and the second alignment line AGL2 in the second direction DR2 may be the fourth distance D4. In the first direction DR1, ends of the first output pads OPD1 and the second output pads OPD2 may be aligned with the third alignment line AGL3.

According to an embodiment, the first distance D1 may be greater than or equal to the fourth distance D4. However, the disclosure is not limited thereto, the first distance D1 may be smaller than the fourth distance D4, and the disclosure is not limited to any one particular embodiment.

According to an embodiment of the disclosure, the output pads OPD of different output pad rows OPD_R may be aligned with each other in the second direction DR2.

The first output pads OPD1 of the first output pad row OPD_R1 may be aligned with the first output pads OPD1 of the second output pad row OPD_R2 in the second direction DR2. The second output pads OPD2 of the first output pad row OPD_R1 may be aligned with the second output pads OPD2 of the second output pad row OPD_R2 in the second direction DR2.

The first output pads OPD1 of the second output pad row OPD_R2 may be aligned with the first output pads OPD1 of the third output pad row OPD_R3 in the second direction DR2. The second output pads OPD2 of the second output pad row OPD_R2 may be aligned with the second output pads OPD2 of the third output pad row OPD_R3 in the second direction DR2.

The first output pads OPD1 and the second output pads OPD2 of the first to fourth output pad rows OPD_R may be aligned in the second direction DR2, so that closeness of the output pads OPD may be improved, and ultra-miniaturization of the display panel DP may be achieved.

It is illustrated in the drawings that all the first output pads OPD1 and the second output pads OPD2 of the first to fourth output pad rows OPD_R are aligned in the second direction DR2, but the disclosure is not limited thereto, only some pads of the first output pads OPD1 may be aligned in the second direction, and the disclosure is not limited to any one particular embodiment. Further, only some pads of the second output pads OPD2 may be aligned in the second direction DR2, and the disclosure is not limited to any one particular embodiment.

An output bump part may include the first to fourth output bump rows OPB_R. It is illustrated in the drawings that distances between adjacent ones of the output bump rows OPB_R are the same, but the disclosure is not limited thereto, the distances may be partially different from each other, and the disclosure is not limited to any one particular embodiment.

Each of the output bump rows OPB_R may include multiple first output bumps OPB1 and multiple second output bumps OPB2.

The first output bumps OPB1 may be arranged in the first direction DR1. The second output bumps OPB2 may be arranged alternately with the first output bumps OPB1 in the first direction DR1.

The second output bumps OPB2 may be arranged to be shifted from the first output bumps OPB1 by a third distance D3 in the second direction DR2. The third distance D3 may be smaller than the second distance D2. However, the disclosure is not limited thereto, and the third distance D3 may be equal to the second distance D2. Further, the third distance D3 may be greater than or equal to the fourth distance D4. As the third distance D3 is made greater than or equal to the fourth distance D4, the reliability of a connection relationship between the output bumps OPB and the output pads OPD may be improved.

The first output bumps OPB1 and the second output bumps OPB2 of the first to fourth output bump rows OPB_R may be connected to the first output pads OPD1 and the second output pads OPD2 of the first to fourth output pad rows OPD_R, respectively. In detail, an arrangement relationship between the first output bumps OPB1 and the second output bumps OPB2 of the first output bump row OPB_R1 may correspond to the first output pads OPD1 and the second output pads OPD2 of the first output pad row OPD_R1. An arrangement relationship between the first output bumps OPB1 and the second output bumps OPB2 of the second output bump row OPB_R2 may correspond to the first output pads OPD1 and the second output pads OPD2 of the second output pad row OPD_R2. This configuration may also be applied to the third output bump row OPB_R3 and the fourth output bump row OPB_R4.

As an example, the first output bumps OPB1 of the first output bump row OPB_R1 may be aligned with the first output bumps OPB1 of the second output bump row OPB_R2 in the second direction DR2, and the second output bumps OPB2 of the first output bump row OPB_R1 may be aligned with the second output bumps OPB2 of the second output bump row OPB_R2 in the second direction DR2.

For example, according to an embodiment of the disclosure, the output pads OPD of each of the output pad rows OPD_R may be arranged in a zigzag shape in the first direction DR1. The output bumps OPB of each of the output bump rows OPB_R may be arranged in a zigzag shape in the first direction DR1 to correspond to the output pads OPD.

Further, the second output pads OPD2 may be shifted by the fourth distance D4 in the second direction DR2 with respect to the first output pads OPD1, and the second output bumps OPB2 may be shifted by the third distance D3 in the second direction DR2 with respect to the first output bumps OPB1. Thus, an area of a region in which the second output bumps OPB2 and the second output pads OPD2 overlap each other may be kept the same, and an area of a region in which the output bumps OPB and the output pads OPD do not overlap each other may decrease. Therefore, ultra-miniaturization of the size of the display device DD may be achieved.

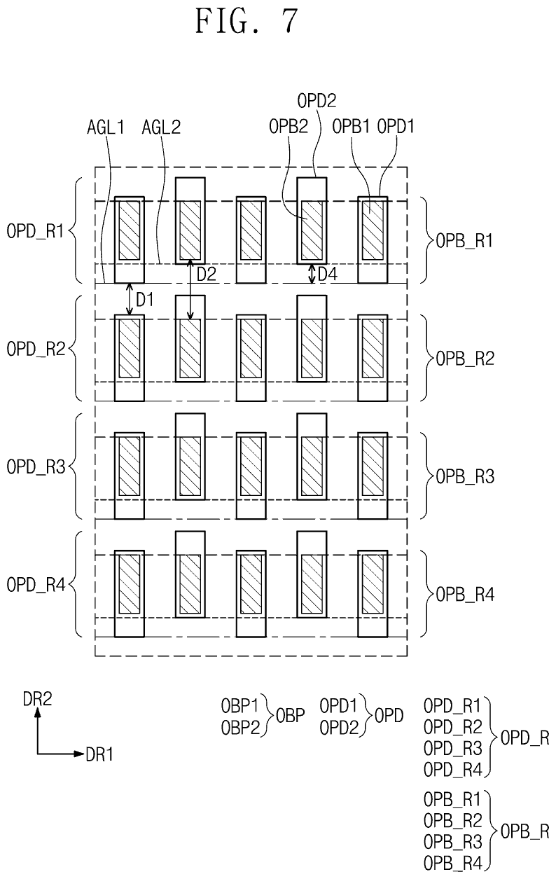

FIG. 7 is an enlarged schematic view of the portion of the chip area of the display device according to an embodiment of the disclosure.

Referring to FIG. 7, even in case that the first output pads OPD1 and the second output pads OPD2 of each of the first to fourth output pad rows OPD_R are arranged in a zigzag shape in the first direction DR1, the first output bumps OPB1 and the second output bumps OPB2 of the first to fourth output bump rows OPB_R may be aligned in the first direction DR1.

Even in this case, the first output pads OPD1 and the second output pads OPD2 of each of the first to fourth output pad rows OPD_R may be arranged in a zigzag shape in the first direction DR1.

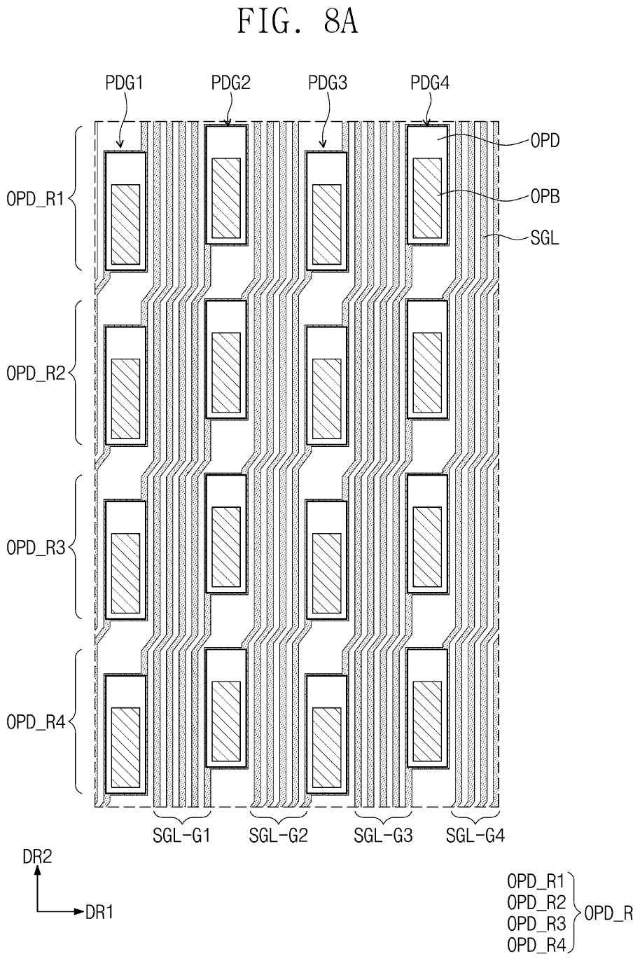

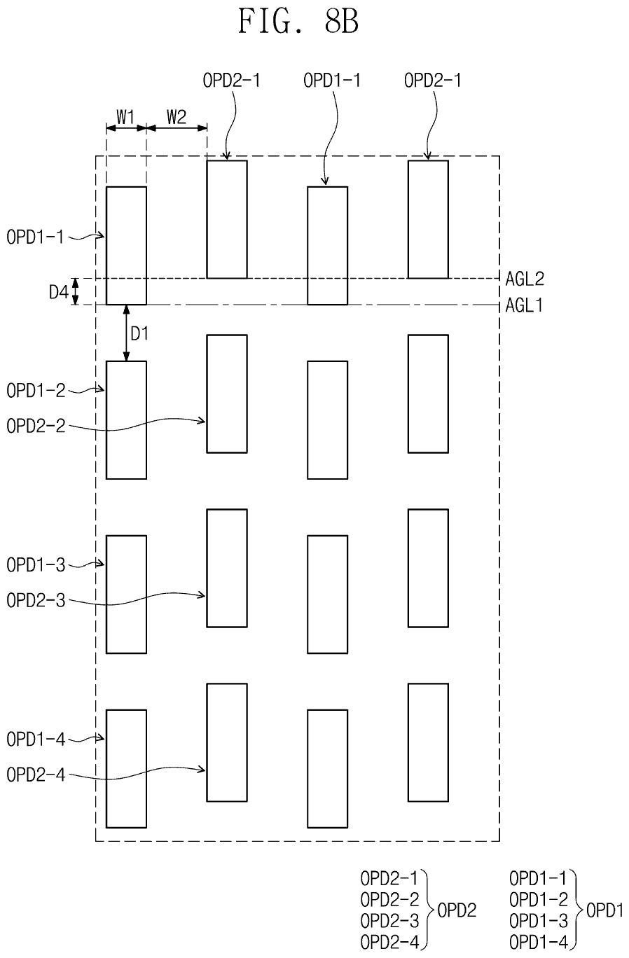

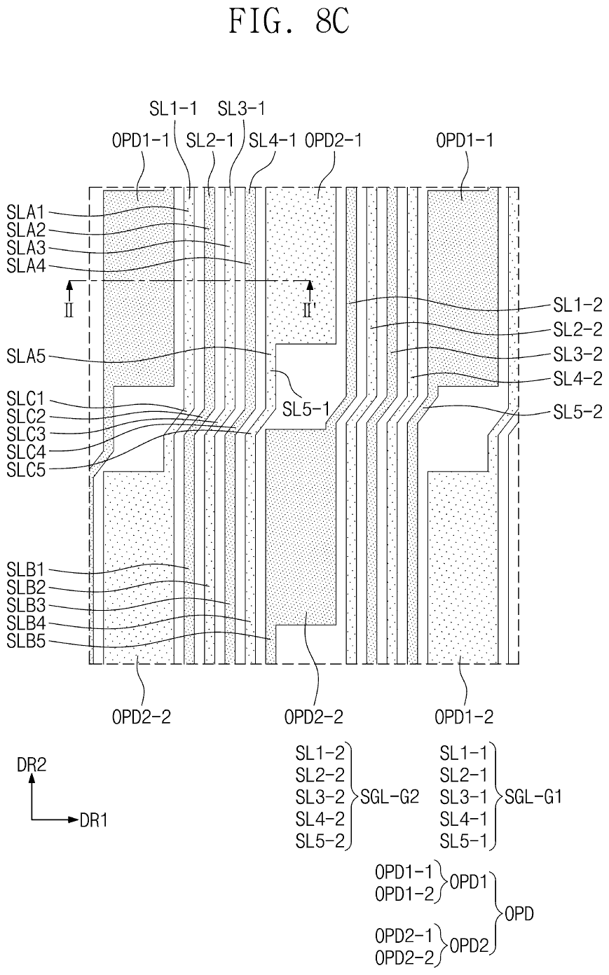

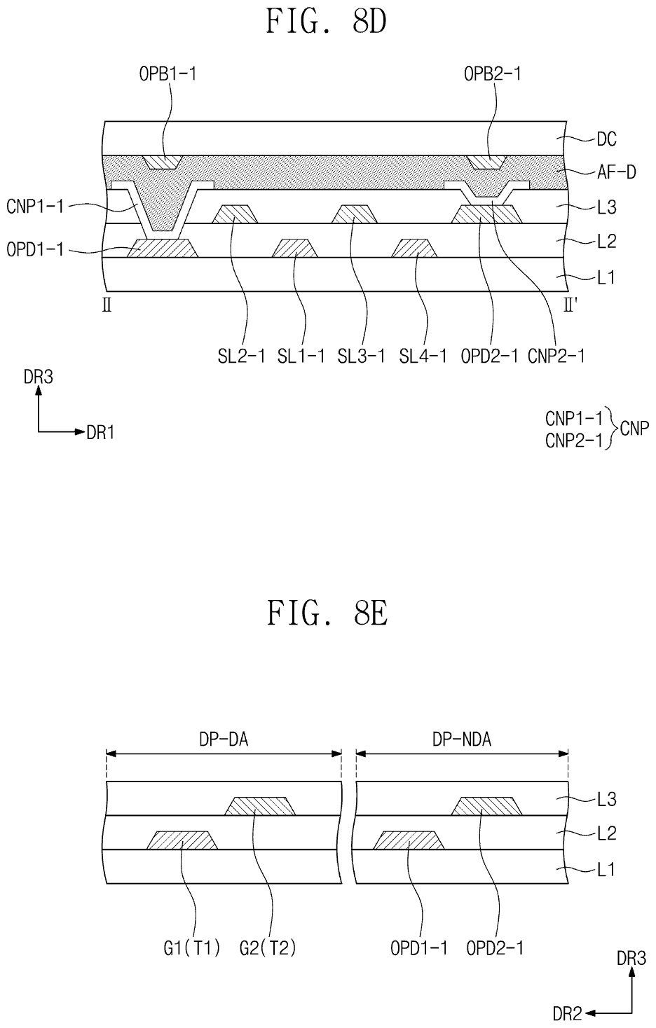

FIGS. 8A to 8C are enlarged schematic plan views of a portion of a pad area of the display device according to an embodiment of the disclosure, and FIGS. 8D and 8E are enlarged cross-sectional views of the portion of the pad area of the display device according to an embodiment of the disclosure.

FIGS. 8A to 8C illustrate the signal lines SGL, the output pads OPD, and the output bumps OPB.

The output pads OPD according to an embodiment of the disclosure may overlap the output bumps OPB and connectors CNP (see FIG. 8D) in plan view, and the output pads OPD, the output bumps OPB, and the connectors CNP (see FIG. 8D) that overlap each other may form respective patterns.

The patterns may be aligned in an arrangement direction of the output pads OPD of the first output pad row OPD_R1. A first pattern PDG1, a second pattern PDG2, a third pattern PDG3, and a fourth pattern PDG4 may be arranged in a zigzag shape in the arrangement direction of the output pads OPD of the first output pad row OPD_R1. This configuration may also be applied to the second output pad row OPD_R2, the third output pad row OPD_R3, and the fourth output pad row OPD_R4.

The signal lines SGL may connect the pixels PX (see FIG. 3) and the first output pads OPD1 (see FIG. 6A) and the second output pads OPD2 (see FIG. 6B). The signal lines SGL may be provided between the first pattern PDG1 and the second pattern PDG2, between the second pattern PDG2 and the third pattern PDG3, and between the third pattern PDG3 and the fourth pattern PDG4. The signal lines SGL may be defined as multiple signal line groups SGL-G1, SGL-G2, SGL-G3, and SGL-G4. Each of the signal line groups SGL-G1, SGL-G2, SGL-G3, and SGL-G4 may include the signal lines SGL.

The first signal line group SGL-G1 may be provided between the first pattern PDG1 and the second pattern PDG2, the second signal line group SGL-G2 may be provided between the second pattern PDG2 and the third pattern PDG3, and the fourth signal line group SGL-G4 may be provided between the third pattern PDG3 and the fourth pattern PDG4. For example, the first signal line group SGL-G1 may be provided between the first pad PD1 and the second pad PD2, and the second signal line group SGL-G2 may be arranged to be spaced apart from the first signal line group SGL-G1 with the second pattern PDG2 interposed therebetween.

Some signal lines SGL of each of the signal line groups SGL-G1, SGL-G2, SGL-G3, and SGL-G4 may be electrically connected to the patterns. Each of the signal lines SGL may electrically connect the pads PD of different output pad rows OPD_R. As an example, some signal lines SGL of the first signal line group SGL-G1 may be electrically connected to one output pad OPD of the second output pad row OPD_R2, and other signal lines SGL of the first signal line group SGL-G1 may be electrically connected to one output pad OPD of the third output pad row OPD_R3.

Some of the signal lines SGL may extend in the second direction DR2, and others thereof may be inclined in the first direction DR1 and the second direction DR2.

The drawings illustrate only the first to fourth signal line groups SGL-G1, SGL-G2, SGL-G3, and SGL-G4, but the disclosure is not limited thereto, an additional signal line group may be further provided to correspond to the number of the output pad rows OPD_R, and the disclosure is not limited to any one particular embodiment.

Referring to FIG. 8B, a first output pad OPD1-1 of the first output pad row OPD_R1 (see FIG. 8A) may have a first width W1, and a distance between the first output pad OPD1-1 and a second output pad OPD2-1 of the first output pad row OPD_R1 may be a second width W2. According to an embodiment of the disclosure, the second width W2 may be greater than the first width W1. The second width W2 may be sufficient to allow the signal lines SGL corresponding to at least the number of pad groups to be spaced apart from each other. As illustrated in FIG. 8C, in case that the four output pad rows OPD_R (see FIG. 8A) are arranged, the second width W2 may have a value enough to allow at least four or more signal lines SGL to be arranged.

A width of each of the signal lines SGL may be smaller than or equal to less than 2 micrometers, and a distance between the signal lines SGL may be 1 micrometer or more and 1.5 micrometers or less. As an example, in case that the width of each of the signal lines SGL is 2 micrometers, and the distance between the signal lines SGL is 1 micrometer, the second width W2 may be 13 micrometers or more, and in an embodiment, 16 micrometers. The first width W1 may be 8 micrometers.

However, in case that the second width W2 is excessively large, a size of the entire base substrate SUB may increase, and thus the second width W2 may not be provided beyond a certain range.

The output pads OPD of each of the output pad rows OPD_R (see FIG. 8A) may have the same shape and may have the first width W1 and the second width W2 having the same value.

According to an embodiment of the disclosure, the fourth distance D4 may be smaller than or equal to the first distance D1. A distance between the first output pad OPD1-1 of the first output pad row OPD_R1 and the first output pad OPD1-2 of the second output pad row OPD_R2 in the second direction DR2 may be the first distance D1, and a distance between the second output pad OPD2-1 of the first output pad row OPD_R1 and the second output pad OPD2-2 of the second output pad row OPD_R2 in the second direction DR2 may be the first distance D1. This configuration may be applied between the first output pad OPD1 or the second output pad OPD2 between adjacent ones of the output pad rows OPD_R.

The second output pads OPD2 may be shifted from the first output pads OPD1 by the fourth distance D4 in the second direction DR2. For example, a distance by which the second output pads OPD2 are shifted may be smaller than a distance between the second output pads OPD2 of different output pad rows OPD_R in the second direction DR2.

Referring to FIGS. 8C and 8A, the output pads OPD may be connected to the signal lines SGL, respectively, and the signal lines SGL may be arranged between adjacent output pads of the output pads OPD of the output pad rows OPD_R.

The first signal line group SGL-G1 may include a first signal line SL1-1, a second signal line SL2-1, a third signal line SL3-1, and a fourth signal line SL4-1. The first to fourth signal lines SL1-1, SL2-1, SL3-1, and SL4-1 may be arranged to be spaced apart from each other in the first direction DR1.

The first to fourth signal lines SL1-1, SL2-1, SL3-1, and SL4-1 of the first signal line group SGL-G1 may be electrically connected to the first output pads OPD1 of different output pad rows OPD_R. Further, the first to fourth signal lines SL1-1, SL2-1, SL3-1, and SL4-1 of the first signal line group SGL-G1 may be electrically connected to the second output pads OPD2 of different output pad rows OPD_R. For example, sides of the first to fourth signal lines SL1-1, SL2-1, SL3-1, and SL4-1 may be connected to the first output pads OPD1, and other sides thereof may be connected to the second output pads OPD2. However, the disclosure is not limited thereto, some signal lines of the first to fourth signal lines SL1-1, SL2-1, SL3-1, and SL4-1 may be connected to the pixels PX, and the disclosure is not limited to any one particular embodiment.

As an example, the first signal line SL1-1 of the first signal line group SGL-G1 may be electrically connected to the first output pad OPD1-2. The first signal line SL1-1 and the second signal line SL2-1 may be arranged in different layers, and the third signal line SL3-1 and the fourth signal line SL4-1 may be arranged on different layers. The first signal line SL1-1 and the second signal line SL2-1 may be electrically isolated from each other, and the third signal line SL3-1 and the fourth signal line SL4-1 may be electrically isolated from each other. Further, the first signal line SL1-1 and the second signal line SL2-1 may not overlap each other in plan view.

The first signal line group SGL-G1 may include a fifth signal line SL5-1. The fifth signal line SL5-1 of the first signal line group SGL-G1 may be electrically connected to the second output pad OPD2-1 adjacent to the fourth signal line SL4-1. Further, the fifth signal line SL5-1 may be electrically connected to the first output pad OPD1 of the output pad row OPD_R, which is different from the first to fourth signal lines SL1-1, SL2-1, SL3-1, and SL4-1.

The second signal line group SGL-G2 may include a first signal line SL1-2, a second signal line SL2-2, a third signal line SL3-2, and a fourth signal line SL4-2. The first to fourth signal lines SL1-2, SL2-2, SL3-2, and SL4-2 may be arranged to be spaced apart from each other in the first direction DR1.

The first to fourth signal lines SL1-2, SL2-2, SL3-2, and SL4-2 of the second signal line group SGL-G2 may be electrically connected to the first output pads OPD1 of different output pad rows OPD_R. Further, the first to fourth signal lines SL1-2, SL2-2, SL3-2, and SLA-2 of the second signal line group SGL-G2 may be electrically connected to the second output pads OPD2 of different output pad rows OPD_R. For example, sides of the first to fourth signal lines SL1-2, SL2-2, SL3-2, and SL4-2 may be connected to the first output pads OPD1, and other sides thereof may be connected to the second output pads OPD2. However, the disclosure is not limited thereto, some signal lines of the first to fourth signal lines SL1-2, SL2-2, SL3-2, and SL4-2 may be connected to the pixels PX, and the disclosure is not limited to such embodiments.

The second signal line group SGL-G2 may include a fifth signal line SL5-2. The fifth signal line SL5-2 of the second signal line group SGL-G2 may be electrically connected to the first output pad OPD1-1 adjacent to the fourth signal line SL4-2. Further, the fifth signal line SL5-2 may be electrically connected to the second output pad OPD2 of the output pad row OPD_R, which is different from the first to fourth signal lines SL1-2, SL2-2, SL3-2, and SL4-2.

The first to fifth signal lines SL1-1, SL2-1, SL3-1, SL4-1, and SL5-1 of the first signal line group SGL-G1 may include first line parts SLA1, SLA2, SLA3, SLA4, and SLA5, second line parts SLB1, SLB2, SLB3, SLB4, and SLB5, and connection parts SLC1, SLC2, SLC3, SLC4, and SLC5. The first line parts SLA1, SLA2, SLA3, SLA4, and SLA5 may extend in the second direction DR2. The second line parts SLB1, SLB2, SLB3, SLB4, and SLB5 may extend in the second direction DR2 and may be spaced apart from the first line parts SLA1, SLA2, SLA3, SLA4, and SLA5 in the second direction DR2. The connection parts SLC1, SLC2, SLC3, SLC4, and SLC5 may connect the first line parts SLA1, SLA2, SLA3, SLA4, and SLA5 and the second line parts SLB1, SLB2, SLB3, SLB4, and SLB5 and may be inclined in the first direction DR1 and the second direction DR2.

The connection parts SLC1, SLC2, SLC3, SLC4, and SLC5 may partially overlap the electrically insulated output pad OPD when viewed in a direction viewed from the second direction DR2. Referring to the drawings, the fifth signal line SL5-1 of the first signal line group SGL-G1 may partially overlap the second output pad OPD2-2 in the direction viewed from the second direction DR2.

According to an embodiment of the disclosure, the second line parts SLB1, SLB2, SLB3, SLB4, and SLB5 may be shifted from the first line parts SLA1, SLA2, SLA3, SLA4, and SLA5 in the first direction DR1. The second line parts SLB1, SLB2, SLB3, SLB4, and SLB5 may be shifted from the first line parts SLA1, SLA2, SLA3, SLA4, and SLA5 and connected from the first line parts SLA1, SLA2, SLA3, SLA4, and SLA5 through the connection parts SLC1, SLC2, SLC3, SLC4, and SLC5, and thus an area of a region occupied by the signal lines SGL may be reduced. Therefore, ultra-miniaturization of the display device may be provided.

The disclosure is not limited thereto, the degree and direction to which the second line parts SLB1, SLB2, SLB3, SLB4, and SLB5 are shifted may vary depending on a direction in which the fifth signal line SL5-1 extends out from the pad PD, and the disclosure is not limited to any one particular embodiment.

The shape and arrangement relationship may also be applied to the signal lines SL1-2, SL2-2, SL3-2, SL4-2, and SL5-2 of the second signal line group SGL-G2.

The line parts SLA1 to SLA5 and SLB1 to SLB5 of the first to fifth signal lines SL1-1, SL2-1, SL3-1, SL4-1, and SL5-1 may extend in the same direction. The connection parts SLC1 to SLC5 of the signal lines SL1-1, SL2-1, SL3-1, SL4-1, and SL5-1 of the first signal line group SGL-G1 or connection parts of the first to fifth signal lines SL1-2, SL2-2, SL3-2, SL4-2, and SL5-2 of the second signal line group SGL-G2 may be aligned with each other in the first direction DR1. The area of the region occupied by the signal lines SGL may be reduced through regular arrangement of the line parts and the connection parts.

However, the disclosure is not limited thereto, the connection parts SLC1 to SLC5 of the signal lines SL1-1, SL2-1, SL3-1, SL4-1, and SL5-1 of the first signal line group SGL-G1 and the connection parts SLC1 to SLC5 of the signal lines SL1-2, SL2-2, SL3-2, SL4-2, and SL5-2 of the second signal line group SGL-G2 may be aligned with each other in the first direction DR1, and the disclosure is not limited to any one particular embodiment.

FIG. 8D is a partial schematic cross-sectional view of the display device of the disclosure in a direction parallel to the first direction DR1. FIG. 8D illustrates a cross-sectional surface along line II-II′ illustrated in FIG. 8C. FIG. 8E is a partial schematic cross-sectional view of the display device of the disclosure in a direction parallel to the second direction DR2.

FIG. 8D is a cross-sectional view of the first output pad row OPD_R (see FIG. 8A) as an example. The first signal line SL1-1 and the second signal line SL1-2 may be arranged in different layers.

The first layer to the third layer L1, L2, and L3 may be sequentially arranged in the third direction DR3. Each of the first layer to the third layer L1, L2, and L3 may be an insulating layer.

The first output pad OPD1-1 and the second signal line SL1-2 may be arranged on the first layer L1. The first output pad OPD1-1 and the second signal line SL1-2 may be formed through the same process. The second output pad OPD2-1 and the first signal line SL1-1 may be arranged on the second layer L2. The second output pad OPD2-1 and the first signal line SL1-1 may be formed through the same process.

The first output pad OPD1-1 and the second output pad OPD2-1 may be arranged on different layers. The first signal line SL1-1 and the second signal line SL1-2 may be arranged in different layers. The first output pad OPD1-1 and the second output pad OPD2-1 and the first signal line SL1-1 and the second signal line SL1-2 may be arranged on different layers and insulated from each other.

Further, the first output pad OPD1-1 and the first signal line SL1-1 may not overlap the second output pad OPD2-1 and the second signal line SL1-2 in plan view. Therefore, coupling between the signal lines SGL may be prevented.

Although not illustrated in the drawings, the first output pad OPD1-1 of the first output pad row OPD_R1 and the first output pad OPD1-2 of the second output pad row OPD_R2 may be arranged on different layers. The first output pad OPD1-1 of the first output pad row OPD_R1 may be disposed on the same layer as that of the second output pad OPD2-2 of the second output pad row OPD_R2. However, the disclosure is not limited thereto, the output pads of each of the output pad rows may be arranged on the same layer, and the disclosure is not limited to any one particular embodiment.

According to an embodiment of the disclosure, the display device may further include the connector CNP. The connector CNP may be provided as multiple connectors CNP, and the number of connectors CNP may be provided to correspond to the number of output pads OPD. FIG. 8D illustrates the connectors CNP corresponding to the output pads OPD of the first output pad row OPD_R1.

A first connector CNP1-1 among the connectors CNP may overlap the first output pad OPD1-1. The first connector CNP1-1 may be connected to the first output pad OPD1-1 through an insulating layer disposed on the first output pad OPD1-1, and a first output bump OPB1-1 may be electrically connected to the first output pad OPD1-1 through the first connector CNP1-1.

A second connector CNP2-1 among the connectors CNP may overlap the second output pad OPD2-1. The second connector CNP2-1 may be connected to the second output pad OPD2-1 through an insulating layer disposed on the second output pad OPD2-1, and a second output bump OPB2-1 may be electrically connected to the second output pad OPD2-1 through the second connectors CNP2-1.

The reliability of electrical connection between the output bumps OPB and the output pads OPD may be ensured through the connectors CNP. However, the connectors CNP may be omitted, and the disclosure is not limited to any one particular embodiment.

Although not illustrated in the drawings, multiple conductive balls may be provided in the second adhesive layer AF-D, and thus the reliability of electrical connection between the output bumps OPB and the output pads OPD may be further improved.

Referring to FIG. 8E, a first gate G1 of a first transistor T1 and a second gate G2 of a second transistor T2 may be arranged on different layers.

The first transistor T1 and the second transistor T2 may overlap the display area, and the first output pad OPD1-1 and the second output pad OPD2-1 may overlap the non-display area.

The first output pad OPD1-1 may be disposed on the same layer as that of the first gate G1. In detail, the first output pad OPD1-1 may be disposed on the first layer L1. Further, the first output pad OPD1-1 may overlap the second layer L2 on a cross section. The second output pad OPD2-1 may be disposed on the same layer as that of the second gate G2. In detail, the second output pad OPD2-1 may overlap the third layer L3 on a cross section.

The first gate G1 of the first transistor T1 and the first output pad OPD1-1 may be formed through the same process. As described above, the first signal line SL1-1, which is disposed on the same layer as that of the first output pad OPD1-1, may also be formed through the same process as that of the first gate G1. The second gate G2 of the second transistor T2 and the second output pad OPD2-1 may be formed through the same process. As described above, the second signal line SL1-2, which is disposed on the same layer as that of the second output pad OPD2-1, may also be formed through the same process as that of the second gate G2.

This configuration may be applied to not only the first signal line SL1-1 (see FIG. 8C) and the second signal line SL2-1 (see FIG. 8C) of the first signal line group SGL-G1 (see FIG. 8C) but also the first signal line SL1-2 (see FIG. 8C) and the second signal line SL2-2 (see FIG. 8C) of the second signal line group SGL-G2 (see FIG. 8C) and may be applied to other signal lines of the first signal line group SGL-G1 (see FIG. 8C) and the second signal line group SGL-G2 (see FIG. 8C), and the disclosure is not limited to any one particular embodiment.

It is illustrated in the drawings that a single layer is disposed between the first gate G1 of the first transistor T1 and the second gate G2 of the second transistor T2, but the disclosure is not limited thereto, multiple layers may be arranged between the first gate G1 and the second gate G2, and the disclosure is not limited to any one particular embodiment.

Further, only the first gate G1 of the first transistor T1 and the second gate G2 of the second transistor T2 are illustrated in the drawings, but the disclosure is not limited thereto, a third gate of a third transistor disposed on a different layer from those of the first gate G1 and the second gate G2 may be provided, the first output pad OPD1-1 or the second output pad OPD2-1 may be disposed on the same layer as that of the third gate, and the disclosure is not limited thereto.

FIG. 8E illustrates the first output pad OPD1-1 and the second output pad OPD2-1 of the first output pad row OPD_R1 (see FIG. 8A), but this configuration may be similarly applied to the second to fourth output pad rows OPD_R2, OPD_R3, and OPD_R4 (see FIG. 8A). Further, in the case of the second output pad row OPD_R2 (see FIG. 8A), the first output pad OPD1-2 (see FIG. 8B) may be disposed on the same layer as that of the second gate G2, and the second output pad OPD2-2 (see FIG. 8B) may be disposed on the same layer as that of the first gate G1.

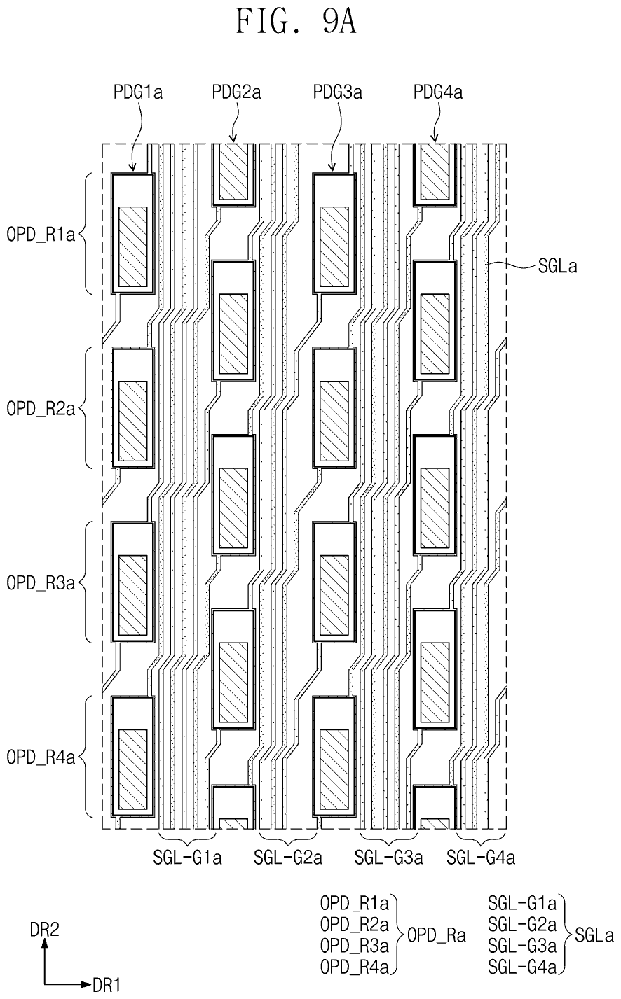

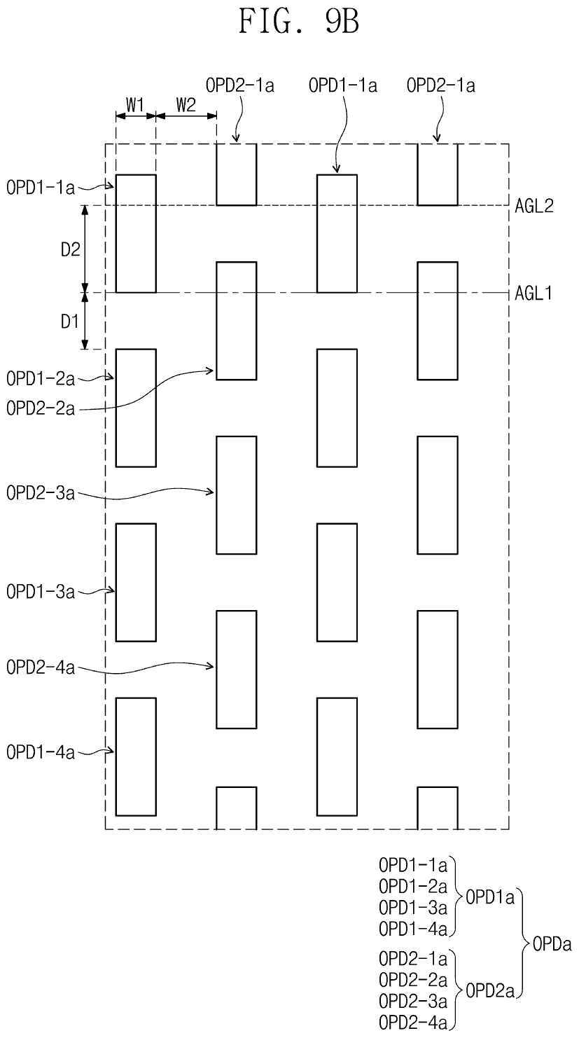

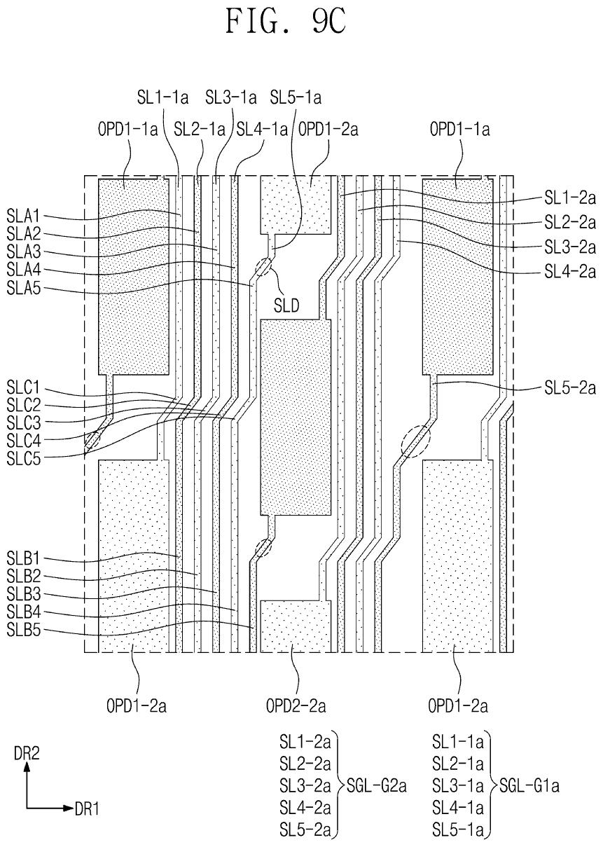

FIGS. 9A to 9C are enlarged schematic plan views of the portion of the pad area of the display device according to an embodiment of the disclosure.

A second output pad OPD2a of an embodiment of the disclosure illustrated in FIGS. 9A to 9C may be shifted further than the second output pad OPD2 of an embodiment of the disclosure illustrated in FIGS. 8A to 8C in the second direction DR2.

A distance between a first output pad OPD1a and the second output pad OPD2a according to an embodiment of FIGS. 9A to 9C may be substantially the same as a distance between the first output pad OPD1 and the second output pad OPD2 described above in FIGS. 8A and 8C, but the disclosure is not limited thereto, and the distance may be greater than or smaller than the distance described above in FIGS. 8A to 8C, and the disclosure is not limited to any one particular embodiment.

Hereinafter, the same components as those according to an embodiment of the disclosure described in the above-described drawings are designated by the same reference numerals, and detailed descriptions thereof will be omitted.

Referring to FIGS. 9A and 9B, as compared to an embodiment of the disclosure illustrated in FIGS. 8A to 8C, there may be some differences in a degree to which the second output pads OPD2a of the output pad rows OPD_Ra are shifted in the second direction DR2 and an extension direction of signal lines SGLa.

According to an embodiment of the disclosure, the above-described fourth distance D4 (see FIG. 7) may be greater than or equal to the first distance D1. For example, a distance by which the second output pads OPD2a are shifted may be greater than or equal to a distance between the first output pad OPD1a of one output pad row and the first output pad OPD1a of another output pad row in the second direction DR2.

Referring to FIG. 9C, the signal lines SGLa (see FIG. 9A) may include a first signal line group SGL-G1a and a second signal line group SGL-G2a. One of a first line part SLA5 and a second line part SLB5 of a fifth signal line SL5-1a of the first signal line group SGL-G1a may include an inclined portion SLD. The inclined portion SLD may be inclined in the first direction DR1 and the second direction DR2. The inclined portion SLD may be shifted from a connection part SLC5 in the first direction DR1. Further, line parts on a side and another side of the inclined portion SLD may be shifted from each other in the first direction.

The inclined portion SLD may not be aligned with the connection part SLC5 of the fifth signal line SL5-1a in the first direction DR1. However, the inclined portions SLD and the connection parts of different signal line groups may be aligned in the first direction DR1, and the disclosure is not limited to any one particular embodiment.

The inclined portion SLD may partially overlap the electrically insulated pad in a direction viewed in the second direction DR2. Referring to the drawings, the fifth signal line SL5-1a of the first signal line group SGL-G1a may partially overlap a second output pad OPD1-2a in a direction viewed from the second direction DR2.

In this way, the inclined portion SLD is provided, and thus even in case that the second distance D2 (see FIG. 9B) is greater than or equal to the first distance D1 (see FIG. 9B), the signal lines SGLa (see FIG. 9A) may be spaced a predetermined or selected distance from each other. Therefore, the expandability of a position design of the pads may increase.

Further, the signal lines SGLa (see FIG. 9A) are spaced a predetermined or selected distance from each other, so that coupling between the signal lines SGLa (see FIG. 9A) may be prevented. Further, the signal lines SGLa (see FIG. 9A) provided on different layers may be prevented from overlapping each other in plan view, so that the coupling may be prevented.

A width of each of the signal lines SGLa (see FIG. 9A) may be 2 micrometers or less, and a distance between the signal lines SGLa (see FIG. 9A) may be 1 micrometer or less. In an embodiment, the width of each of the signal lines SGLa (see FIG. 9A) may be 1 micrometer, and the distance between the signal lines SGLa (see FIG. 9A) may be 0.5 micrometer. The distance between the signal lines SGLa (see FIG. 9A) is 0.5 micrometer or less, so that the closeness of the signal lines SGLa (see FIG. 9A) in an area between output pads OPDa (see FIG. 9B) may be improved. Further, a decrease in the closeness of the signal lines SGLa (see FIG. 9A), which is caused by an addition of the inclined portion SLD, may be prevented.

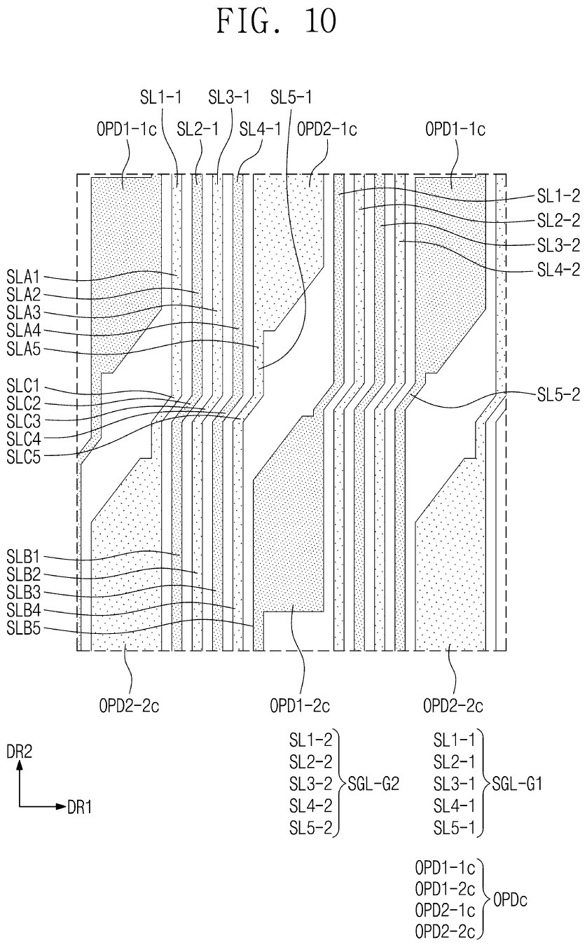

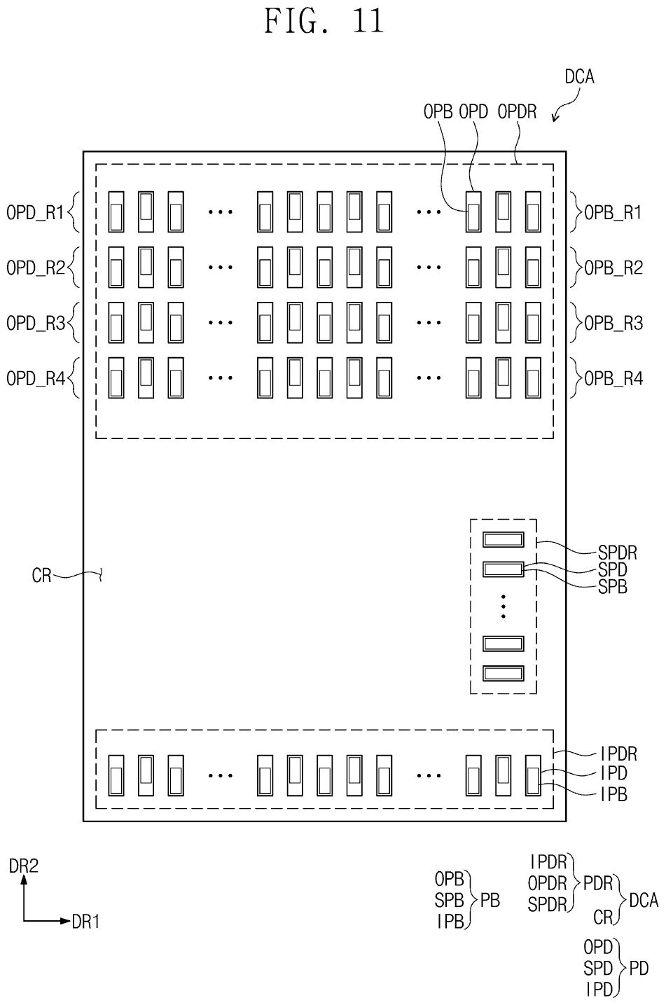

FIG. 10 is an enlarged schematic plan view of the portion of the pad area of the display device according to an embodiment of the disclosure.

Hereinafter, the same components as those according to an embodiment of the disclosure described in the above-described drawings are designated by the same reference numerals, and detailed descriptions thereof will be omitted.

Referring to FIG. 10, output pads OPD1-1c, OPD2-1c, OPD1-2c, and OPD2-2c of the disclosure may have a shape other than a rectangle. As an example, the output pads OPD1-1c, OPD2-1c, OPD1-2c, and OPD2-2c of the disclosure may have a shape of which some edges are cut out. Therefore, an area through which signal lines SGL-1 and SGL-2 may pass may increase. With the area, the degree of freedom for a distance between the output pads OPD1-1c, OPD2-1c, OPD1-2c, and OPD2-2c and an extended or inclined shape of the signal lines SGL-G1 and SGL-G2 may be secured.

FIG. 11 is a schematic plan view of the chip area of the display device according to an embodiment of the disclosure.

Referring to FIG. 11, the input pad part IPDR may include the input pads IPD.

The input pads IPD may have the same shape and may be arranged parallel to each other.

The driving chip DC (see FIG. 4) may include the input bumps IPB connected to the input pads IPD. The input bumps IPB may overlap the input pads IPD in plan view.

The input bumps IPB may have the same shape. Further, the input bumps IPB may have a partially symmetrical shape, and the disclosure is not limited to any one particular embodiment.

According to an embodiment of the disclosure, the input bumps IPB arranged in the same row may be arranged to be offset from each other in a zigzag shape in the first direction DR1. For example, the input bumps IPB adjacent to each other may be shifted by a predetermined or selected distance in the second direction DR2 and may be arranged to be partially offset from each other.

The input bumps IPB may be arranged in a zigzag shape, and thus in case that heat and pressure is applied to the driving chip DC (see FIG. 4) to electrically connect the input pads IPD and the input bumps IPB, deformation or cracks may be prevented from occurring due to a pressure (or a stress) concentrated on areas adjacent to the input pads IPD. For example, in case that the pressure (or the stress) is applied to the areas adjacent to the input pads IPD, the applied portions are prevented from being arranged with a certain rule in a specific one direction (e.g., the first direction DR1), and thus the pressure (or the stress) may be uniformly distributed throughout the display panel DP (see FIG. 4). Therefore, the entire display panel DP (see FIG. 4) may be prevented from being deformed due to local deformation inside the display panel DP (see FIG. 4).

In the case of an embodiment of the disclosure in which the input bumps IPB are arranged in a zigzag shape, the pressure (or the stress) applied to the areas adjacent to the input pads IPD may be reduced by 8% to 13% as compared to a case (comparative example) in which all the input bumps IPB and the input pads IPD are not arranged in a zigzag shape.

Further, in the case of an embodiment of the disclosure, the amount of deformation of the display panel in a thickness direction may be reduced by 16% to 17% as compared to the above-described comparative example.

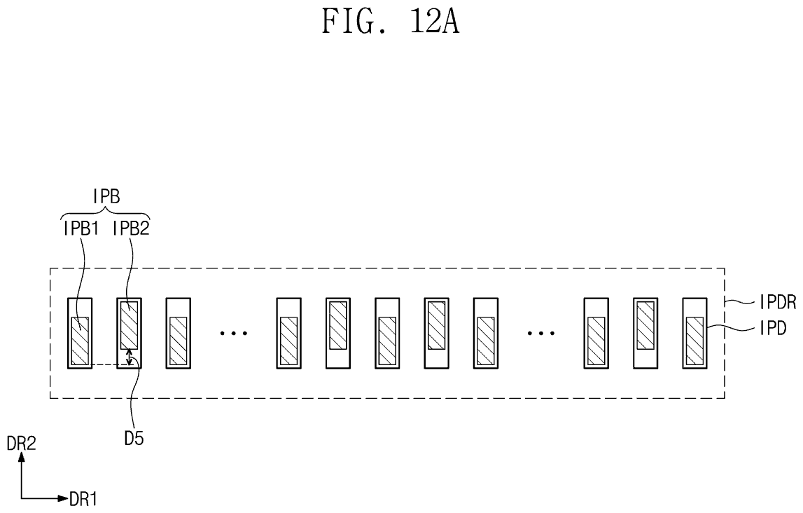

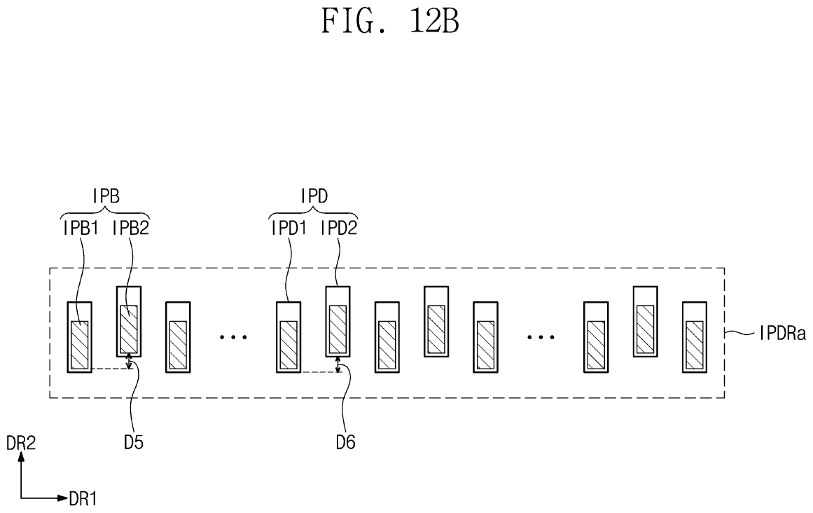

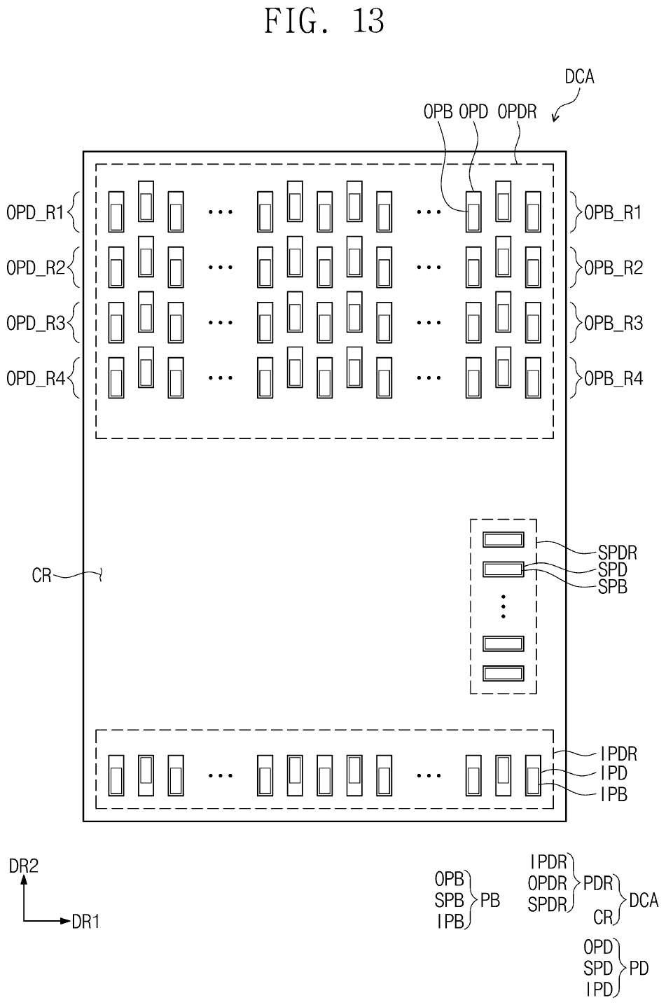

FIGS. 12A and 12B are enlarged schematic plan views of the portion of the pad area of the display device according to an embodiment of the disclosure. FIG. 12A is an enlarged plan view of the input pad part IPDR illustrated in FIG. 11, and FIG. 12B is a plan view of an input part IPDRa according to an embodiment different from an embodiment of the disclosure illustrated in FIG. 12A.

Referring to FIG. 12A, the input bumps IPB may include multiple first input bumps IPB1 and multiple second input bumps IPB2. The input bumps IPB1 and IPB2 may be arranged to be offset from each other in a zigzag shape in the first direction DR1. For example, the input bumps IPB adjacent to each other may be shifted by a predetermined or selected distance in the second direction DR2 and may be arranged to be partially offset from each other.

Referring to the drawings, the second input bumps IPB2 may be arranged to be shifted from the first input bumps IPB1 by a fifth distance D5 in the second direction DR2.

Referring to FIG. 12B, the input pads IPD may include multiple first input pads IPD1 and multiple second input pads IPD2.

The first input pads IPD1 may be arranged in the first direction DR1. The second input pads IPD2 may be arranged alternately with the first input pads IPD1 in the first direction DR1. The second input pads IPD2 may be arranged to be shifted from the first input pads IPD1 by a predetermined or selected distance in the second direction DR2.

Referring to the drawings, the second input bumps IPB2 may be arranged to be shifted from the first input bumps IPB1 by the fifth distance D5 in the second direction DR2. Further, the second input pads IPD2 may be arranged to be shifted from the first input pads IPD1 by a sixth distance D6 in the second direction DR2.

The sixth distance D6 may be smaller than or equal to the fifth distance D5. Areas occupied by the input pads IPD and the input bumps IPB in the chip area DCA may be adjusted by adjusting a difference between the fifth distance D5 and the sixth distance D6.

Cracks or damages that may occur in case that the driving chip DC (see FIG. 4) is mounted may be minimized due to the arrangement of the input pads IPD1 and IPD2 arranged in a zigzag shape and/or the arrangement of the input bumps IPB1 and IPB2 arranged in a zigzag shape.

FIG. 13 is a schematic plan view of the chip area of the display device according to an embodiment of the disclosure.

In the chip area of the display device illustrated in FIG. 13, as described above in FIG. 5, the output pads OPD and the output bumps OPB may be arranged in a zigzag shape in the first direction DR1.

Further, as described above in FIG. 12, the input bumps IPB may be arranged in a zigzag shape in the first direction DR1. Further, the disclosure is not limited thereto, the input pads IPD may also be arranged in a zigzag shape in the first direction DR1, and the disclosure is not limited to any one particular embodiment.

In a display device according to an embodiment of the disclosure, a driving chip may be safely mounted on a substrate without cracks or damage.

In the display device according to an embodiment of the disclosure, ultra-miniaturization of the display device may be achieved, and manufacturing costs may be reduced.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure.

What is claimed is:

1. A display device, comprising:
a display panel including a plurality of first row output pads arranged in a first direction and a plurality of second row output pads spaced apart from the plurality of first row output pads in a second direction intersecting the first direction by a first distance; and
a driving chip including a plurality of first row output bumps arranged in the first direction and contacting the plurality of first row output pads and a plurality of second row output bumps spaced apart from the plurality of first row output bumps in the second direction by a second distance that is greater than or equal to the first distance and contacting the plurality of second row output pads, wherein
each of the plurality of first row output pads and each of the plurality of second row output pads respectively includes:
a plurality of first output pads arranged in the first direction; and
a plurality of second output pads aligned in the first direction, arranged alternately with the plurality of first output pads in the first direction, and shifted from the plurality of first output pads in the second direction by a fourth distance, and
each of the plurality of first row output bumps and each of the plurality of second row output bumps includes:
a plurality of first output bumps aligned in the first direction and contacting the plurality of first output pads; and
a plurality of second output bumps aligned in the first direction, connected to the plurality of second output pads, and shifted from the plurality of first output bumps in the second direction by a third distance.

2. The display device of claim 1, wherein the fourth distance is smaller than the first distance.

3. The display device of claim 1, wherein the third distance is smaller than the second distance.

4. The display device of claim 1, wherein the fourth distance is smaller than or equal to the third distance.

5. The display device of claim 1, wherein
the plurality of first output pads of the plurality of first row output pads are aligned with the plurality of second output pads of the plurality of second row output pads in the second direction, and
the plurality of second output pads of the plurality of first row output pads are aligned with the plurality of first output pads of the plurality of second row output pads in the second direction.

6. The display device of claim 1,
the display panel further includes:
a plurality of pixels; and
a plurality of signal lines connecting the plurality of pixels with both the plurality of first row output pads and the plurality of second row output pads,
the plurality of signal lines include:
a first signal line group including signal lines arranged between one of the plurality of first output pads and one of the plurality of second output pads adjacent to each other among the plurality of first row output pads; and
a second signal line group including signal lines spaced apart from the first signal line group in the first direction with the one of the plurality of second output pads disposed between the second signal line group and the first signal line group, and
each of the first signal line group and the second signal line group includes:
a first signal line connected to any one of the plurality of first output pads and the plurality of second output pads; and
a second signal line electrically insulated from the first signal line.

7. The display device of claim 6, wherein
each of the plurality of signal lines includes:
a first line part parallel to the second direction;
a second line part parallel to the second direction and spaced apart from the first line part in the second direction; and
a connection part connecting the first line part and the second line part and inclined in the first direction and the second direction, and
the second line part is shifted from the first line part in the first direction.

8. The display device of claim 7, wherein each connection part of the signal lines of the first signal line group and each connection part of the signal lines of the second signal line group are aligned in the first direction.

9. The display device of claim 6, wherein
each of the plurality of pixels includes:
a first transistor including a first gate; and
a second transistor including a second gate disposed on a different layer from the first gate,
the first signal line and the first gate are disposed on a same layer, and
the second signal line and the second gate are disposed on a same layer.

10. The display device of claim 9, wherein the first signal line and the second signal line do not overlap each other in plan view.

11. The display device of claim 9, further comprising:
a connection part passing through an insulating layer disposed on one of the plurality of first output pads and connected to the one of the plurality of first output pads,
wherein one of the plurality of first output bumps is electrically connected to the one of the plurality of first output pads through the connection part.

12. The display device of claim 7, wherein
each of the first signal line group and each of the second signal line group respectively further includes:
a third signal line electrically insulated from the second signal line and spaced apart from the first signal line with the second signal line disposed between the third signal line and the first signal line,
each of the first to third signal lines respectively includes:
a first line part parallel to the second direction;
a second line part parallel to the second direction, spaced apart from the first line part in the second direction, and shifted from the first line part in the first direction; and
a connection part connecting the first line part and the second line part and inclined in the first direction and the second direction, and
the first line part of the third signal line or the second line part of the third signal line further includes an inclined portion shifted from the connection part of the third signal line in the first direction.

13. The display device of claim 12, wherein
each connection part of the first to third signal lines are aligned in the first direction, and
the fourth distance is greater than or equal to the first distance.

14. The display device of claim 1, wherein
the display panel further includes a plurality of input pads spaced apart from the plurality of second row output pads in the second direction and arranged in the first direction,
the driving chip further includes a plurality of input bumps spaced apart from the plurality of second row output bumps in the second direction and connected to the plurality of input pads, and
the plurality of input bumps include:
a plurality of first input bumps aligned in the first direction; and
a plurality of second input bumps aligned in the first direction, arranged alternately with the plurality of first input bumps in the first direction, and shifted from the plurality of first input bumps in the second direction by a fifth distance.

15. The display device of claim 14, wherein
the input pads include:
a plurality of first input pads aligned in the first direction and electrically connected to the plurality of first input bumps; and
a plurality of second input pads aligned in the first direction and electrically connected to the plurality of second input bumps, and
the plurality of second input pads are shifted from the plurality of first input pads in the second direction by a sixth distance.

16. The display device of claim 15, wherein the sixth distance is smaller than or equal to the fifth distance.

17. A display device, comprising:
a display panel including:
a plurality of first row output pads arranged in a first direction;
a plurality of second row output pads spaced apart from the plurality of first row output pads in a second direction intersecting the first direction by a first distance; and
a plurality of input pads spaced apart from the plurality of second row output pads in the second direction and arranged in the first direction; and
a driving chip including:
a plurality of first row output bumps arranged in the first direction and connected to the plurality of first row output pads;
a plurality of second row output bumps spaced apart from the plurality of first row output bumps in the second direction by a second distance that is greater than or equal to the first distance and connected to the plurality of second row output pads; and
a plurality of input bumps spaced apart from the plurality of second row output bumps in the second direction and connected to the plurality of input pads, wherein
each of the plurality of first row output bumps and the plurality of second row output bumps includes:
a plurality of first output bumps aligned in the first direction; and
a plurality of second output bumps aligned in the first direction, arranged alternately with the plurality of first output bumps in the first direction, and shifted from the plurality of first output bumps in the second direction by a third distance, and
the plurality of input bumps include:
a plurality of first input bumps aligned in the first direction; and
a plurality of second input bumps aligned in the first direction, arranged alternately with the plurality of first input bumps in the first direction, and shifted from the plurality of first input bumps in the second direction.

18. The display device of claim 17, wherein
each of the plurality of first row output pads and the plurality of second row output pads includes:
a plurality of first output pads aligned in the first direction and electrically connected to the plurality of first output bumps; and
a plurality of second output pads aligned in the first direction, arranged alternately with the plurality of first output pads in the first direction, and electrically connected to the plurality of second output bumps, and
the plurality of second output pads are shifted from the plurality of first output pads in the second direction by a fourth distance.

19. The display device of claim 17, wherein
the plurality of input pads include:
a plurality of first input pads aligned in the first direction and electrically connected to the plurality of first input bumps; and
a plurality of second input pads aligned in the first direction and electrically connected to the plurality of second input bumps, and
the second input pads are shifted from the first input pads in the second direction.
